(19) United States
(12) Patent Application Publication
(10) Pub. No.: US 2026/0090255 A1
(43) Pub. Date: Mar. 26, 2026

(54) LIGHT EMITTING DEVICE, DISPLAY DEVICE, PHOTOELECTRIC CONVERSION DEVICE, ELECTRONIC APPARATUS, ILLUMINATION DEVICE, MOVING BODY, AND WEARABLE DEVICE

(71) Applicant: CANON KABUSHIKI KAISHA, Tokyo (JP)

(72) Inventors: YOSHIHISA KAWAMURA, Kanagawa (JP); SHOMA HINATA, Kanagawa (JP); TAKAYUKI ITO, Kanagawa (JP)

(21) Appl. No.: 19/327,244

(22) Filed: Sep. 12, 2025

(30) Foreign Application Priority Data
Sep. 26, 2024 (JP) 2024-167824

(51) Int. Cl. H10K 59/80

(52) U.S. Cl. CPC H10K 59/879; H10K 59/878

(57) ABSTRACT

A light emitting device is provided. The device includes a display region where a plurality of pixels are arranged. Each pixel includes a light emitting region arranged on the substrate, a microlens arranged on the light emitting region, and a light shielding layer that includes an opening portion at a position overlapping a vertex of the microlens and covers a part of the microlens. The plurality of pixels include a first pixel, and in the first pixel, the vertex of the microlens and a geometric centroid of the light emitting region are arranged at different positions and a distance between a geometric centroid of the opening portion and the geometric centroid of the light emitting region is shorter than a distance between the vertex of the microlens and the geometric centroid of the light emitting region.

### BACKGROUND

### Field of the Technology

The present disclosure relates to a light emitting device, a display device, a photoelectric conversion device, an electronic apparatus, an illumination device, a moving body, and a wearable device.

### Description of the Related Art

A light emitting device including a light emitting element using an organic electroluminescence (EL) element is known. Japanese Patent Laid-Open No. 2020-184478 describes that in order to improve the view angle characteristic of a display device and increase the radiation angle, the center position of the lens of a pixel and the center position of a pixel electrode are arranged while being shifted from each other in accordance with an arrangement position in a display region.

### SUMMARY

A pixel arranged in a light emitting device is often designed so that light of a desired wavelength can be extracted mainly in the normal direction with respect to a substrate. Therefore, light emitted obliquely with respect to the normal direction may deviate from a desired wavelength and may be emitted from the pixel in a state in which color purity is low. As described in Japanese Patent Laid-Open No. 2020-184478, in a case where the center position of the lens of the pixel and the center position of the pixel electrode are arranged while being shifted from each other, components of light emitted obliquely with respect to the normal direction can increase. If light with low color purity is emitted from the pixel, the color gamut of the light emitting device may be reduced.

Some embodiments of the present disclosure provide a technique advantageous in suppressing reduction of a color gamut.

According to some embodiments, a light emitting device comprising: a display region where a plurality of pixels are arranged on a main surface of a substrate, wherein each pixel includes a light emitting region arranged on the substrate, a microlens arranged on the light emitting region, and a light shielding layer that includes an opening portion at a position overlapping a vertex of the microlens in an orthogonal projection to the main surface and covers a part of the microlens, the plurality of pixels include a first pixel, and in the first pixel, in the orthogonal projection to the main surface, the vertex of the microlens and a geometric centroid of the light emitting region are arranged at different positions and a distance between a geometric centroid of the opening portion and the geometric centroid of the light emitting region is shorter than a distance between the vertex of the microlens and the geometric centroid of the light emitting region, is provided.

Features of the present disclosure will become apparent from the following description of embodiments with reference to the attached drawings. The following description of embodiments is described by way of example.

### BRIEF DESCRIPTION OF THE DRAWINGS

FIGS. 1A and 1B are plan views showing an example of the configuration of a light emitting device according to an embodiment;

FIG. 2 is a sectional view showing an example of the configuration of a light emitting device according to a comparative example;

FIGS. 3A and 3B are sectional views each showing an example of the configuration of a light emitting element of the light emitting device according to the embodiment;

FIGS. 4A and 4B are sectional views each showing an example of the configuration of the light emitting element of the light emitting device according to the embodiment;

FIGS. 5A and 5B are plan views showing an example of the configuration of the light emitting device according to the embodiment;

FIGS. 6A to 6C are plan views showing the example of the configuration of the light emitting device according to the embodiment;

FIGS. 7A to 7C are sectional views showing the example of the configuration of the light emitting device according to the embodiment;

FIGS. 8A to 8E are sectional views showing an example of a manufacturing method of the light emitting device according to the embodiment;

FIGS. 9A and 9B are sectional views showing an example of the configuration of a pixel of the light emitting device according to the embodiment;

FIG. 10 is a view showing an example of a display device using the light emitting device according to the embodiment;

FIG. 11 is a view showing an example of a photoelectric conversion device using the light emitting device according to the embodiment;

FIG. 12 is a view showing an example of an electronic apparatus using the light emitting device according to the embodiment;

FIGS. 13A and 13B are views each showing an example of a display device using the light emitting device according to the embodiment;

FIGS. 14A and 14B are views showing an example of a moving body using the light emitting device according to the embodiment; and

FIGS. 15A and 15B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

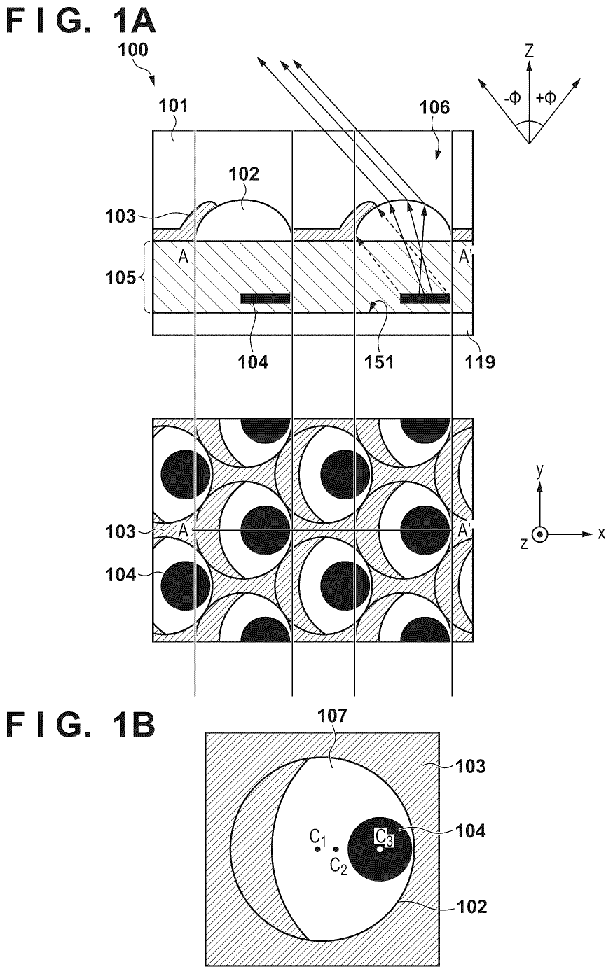

A light emitting device according to an embodiment of the present disclosure will be described with reference to FIGS. 1A to 8E. FIG. 1A shows a sectional view and a plan view showing an example of the configuration of a light emitting device 100 according to this embodiment. The sectional view shown on the upper side of FIG. 1A shows a section taken along a line A-A′ in the plan view shown on the lower side of FIG. 1A.

The light emitting device 100 includes a display region where a plurality of pixels 106 are arranged on a main surface 151 of a substrate 119. Each pixel 106 includes a light emitting element 105 arranged on the substrate 119 and including a light emitting region 104, a microlens 102 arranged on the light emitting region 104, and a light shielding layer 103 that includes an opening portion at a position overlapping the vertex of the microlens 102 in an orthogonal projection to the main surface 151 of the substrate 119 and covers a part of the microlens 102. As shown in FIG. 1B, in the orthogonal projection to the main surface 151 of the substrate 119, the geometric centroid of the light emitting region 104 in each pixel 106 can be arranged at a position overlapping the microlens 102 of each pixel 106. As shown in FIG. 1B, the vertex of the microlens 102 will sometimes be referred to as a vertex C1 hereinafter, and the geometric centroid of the light emitting region 104 will sometimes be referred to as a geometric centroid C3 hereinafter. In addition, the opening portion of the light shielding layer 103 arranged at the position overlapping the vertex of the microlens 102 will sometimes be referred to as an opening portion 107, and the geometric centroid of the opening portion 107 in the orthogonal projection to the main surface 151 of the substrate 119 will sometimes be referred to as a geometric centroid C2 hereinafter.

In the configuration shown in FIGS. 1A and 1B, each of the microlens 102 and the light emitting region 104 is circular in the orthogonal projection to the main surface 151 of the substrate 119. However, the present disclosure is not limited to this. Each of the microlens 102 and the light emitting region 104 may have, for example, a triangular shape, a rectangular shape, or a polygonal shape with five or more sides such as a hexagonal shape in the orthogonal projection to the main surface 151 of the substrate 119. For example, the microlens 102 may be an aspherical lens or the like.

As shown in FIG. 1A, the light emitting device 100 can include a low refractive index layer 101 so as to cover the microlens 102, the light shielding layer 103, the light emitting element 105, and the like. The low refractive index layer 101 may be a gas represented by air or a solid such as a resin or polysiloxane. In a case where the low refractive index layer 101 is a solid, the refractive index of the solid such as a resin may be lowered by adding hollow silica or the like to the solid such as a resin. In a case where the low refractive index layer 101 is a gas, the low refractive index layer 101 can be formed by adopting a package with a hollow structure and introducing a gas into a hollow part. In a case where the low refractive index layer 101 is a solid, the low refractive index layer 101 can be formed by creating a resist by dissolving a low refractive index material in a solvent, applying the resist using a spin coating method or an inkjet method, and curing the resist.

For the light shielding layer 103, for example, a resin containing a black pigment such as carbon black or titanium black, or the like can be used. For example, a black resist composed of a pigment, dispersant, resin, additive, polymerization initiator, solvent, or the like is created, and applied using the spin coating method or the inkjet method. Next, the light shielding layer 103 is formed in a desired region by performing, for example, patterning using a photolithography method.

For the microlens 102, for example, acrylic resin, epoxy resin, polyhydroxystyrene (PHS) resin, novolac resin, or the like is used. The refractive index of the resin may be improved by adding a filler such as titanium oxide or zirconium oxide to the resin. The refractive index of the microlens 102 in a visible light region (a wavelength of 400 nm to 800 nm) is, for example, about 1.5 to 1.7. The microlens 102 can be formed from the above-described resin applied onto the light emitting element 105 using a thermal flow method, an etch back method, a gray tone mask method, or the like.

In the thermal flow method, first, a microlens resist having photosensitivity is created, and a resist film is deposited using the spin coating method or the inkjet method. Next, for example, the resist film is patterned using the photolithography method. Then, the patterned resist film is heated at a temperature equal to or higher than the glass transition temperature of the resin forming the resist film to liquefy (cause thermal flow of) the resist pattern, and thus the resin (resist film) is deformed into a lens shape by the surface tension. The deformed resin is cooled and solidified, thereby forming the microlens 102.

In the etch back method, a resin that is to form the microlens 102 is stacked and a microlens resist having photosensitivity is stacked thereon. Next, an etching mask is formed from the microlens resist using the same thermal flow method as described above. The microlens resist patterned and changed into the lens shape is used as an etching mask to perform etch-back transfer to a lower resin layer, thereby forming the microlens 102. For example, reactive ion etching (RIE) method or the like is used for etch-back transfer.

In the gray tone mask method, first, a resin layer that is to form the microlens 102 is formed. Next, patterning is performed by the photolithography method using a gray tone mask with a locally adjusted transmittance, thereby forming the microlens 102.

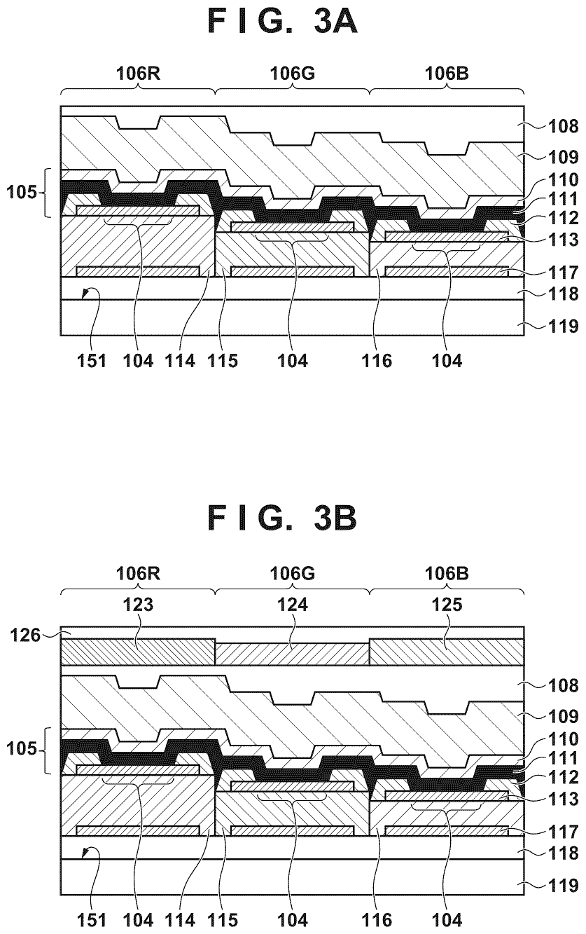

FIG. 3A is a sectional view showing the light emitting element 105 in more detail according to this embodiment. The light emitting element 105 arranged in each pixel 106 can include an upper electrode 110 arranged on the substrate 119, a lower electrode 113 arranged between the upper electrode 110 and the substrate 119, and an organic compound layer 111 arranged between the upper electrode 110 and the lower electrode 113. In addition, in the configuration of the light emitting device 100 shown in FIG. 3A, a reflective layer 117 is arranged between the lower electrode 113 and the substrate 119, and each of optical adjustment layers 114 to 116 is arranged between the lower electrode 113 and the reflective layer 117. In the light emitting device 100, a sealing layer 109 is arranged on the upper electrode 110, and a planarizing layer 108 is arranged on the sealing layer 109. A wiring structure 118 can be arranged between the substrate 119 and the reflective layer 117.

The planarizing layer 108 can be formed for the purpose of planarizing unevenness of the surface (upper surface) of the light emitting element 105. By adjusting the film thickness of the planarizing layer 108, the focal position of the microlens 102 arranged on the planarizing layer 108 can be aligned with the position of the light emitting region 104. For example, the microlens 102 may be arranged in contact with the planarizing layer 108. The light emitting region 104 can be regarded as a portion of the organic compound layer 111 where the lower electrode 113 and the organic compound layer 111 are in contact with each other in the orthogonal projection to the main surface 151 of the substrate 119. To form the planarizing layer 108, a liquid white resist composed of a resin, additive, solvent, or the like may be used. As the resin, acrylic resin, epoxy resin, PHS resin, novolac resin, or the like can be used. Next, the planarizing layer 108 can be formed by applying the white resist using the spin coating method, the inkjet method, or the like, and curing it.

The sealing layer 109 is transmissive, and suppresses permeation of oxygen or water from the outside of the light emitting element 105 to the light emitting element 105. A so-called silicon oxide material such as silicon nitride (SiN), silicon oxynitride (SiON), or silicon oxide (SiOₓ), aluminum oxide (Al₂O₃), titanium oxide (TiO₂), a multilayered film thereof, or the like can be used for the sealing layer 109. To form the sealing layer 109, a chemical vapor deposition (CVD) method, an atomic layer deposition (ALD) method, a sputtering method, or the like can be used.

The upper electrode 110 is arranged on the organic compound layer 111. Therefore, the upper electrode 110 is transmissive. The upper electrode 110 may reflect a part of light entering from the side of the substrate 119 with respect to the upper electrode 110. Thus, the upper electrode 110 is sometimes called a semi-transmissive electrode. As a material forming the upper electrode 110, for example, a transparent material (indium tin oxide (ITO), indium zinc oxide (IZO), or the like) such as a transparent conductive oxide may be used. Alternatively, for example, as a material forming the upper electrode 110, a semi-transmissive material of a metal such as aluminum, silver, or gold, an alkali metal such as lithium or cesium, an alkaline earth metal such as magnesium, calcium, or barium, or an alloy material containing these metal materials may be used.

The organic compound layer 111 includes a light emitting layer. In addition to the light emitting layer, the organic compound layer 111 may include a hole injection layer, a hole transport layer, an electron blocking layer, a hole blocking layer, an electron transport layer, and an electron injection layer. The light emitting element 105 having this configuration can also be called an organic light emitting element, an organic EL element, an organic light emitting diode (OLED), or the like. The organic compound layer 111 (light emitting layer) emits light by injecting electrons and holes from the pair of electrodes (the upper electrode 110 and the lower electrode 113) to the organic compound layer 111. The organic compound layer 111 can be formed using a deposition method or the spin coating method.

In the configuration shown in FIG. 3A, the lower electrode 113 is a transparent electrode that transmits light emitted from the organic compound layer 111. As the lower electrode 113, for example, ITO, IZO, aluminum zinc oxide (AZO), indium gallium zinc oxide (IGZO), or the like can be used. The lower electrode 113 is isolated for each pixel 106 by a pixel isolation layer 112. The pixel isolation layer 112 can also be called a bank or the like. A silicon oxide or silicon nitride film or the like can be used as the pixel isolation layer.

The reflective layer 117 is provided between the lower electrode 113 (light emitting region 104) and the substrate 119. For the reflective layer 117, a material having a refractive index of 70% or more with respect to light emitted from the light emitting layer of the organic compound layer 111 may be used. A metal such as aluminum or silver, an alloy thereof added with silicon, copper, nickel, neodymium, or the like, a transparent oxide film of ITO, IZO, or the like, or a multilayered film thereof can be used as the reflective layer 117.

Each of the optical adjustment layers 114 to 116 is arranged between the lower electrode 113 and the reflective layer 117. For example, the pixels 106 can include a pixel 106R that emits red light, a pixel 106G that emits green light, and a pixel 106B that emits blue light. In the configuration shown in FIG. 3A, the optical adjustment layer 114 is arranged in the pixel 106R, the optical adjustment layer 115 is arranged in the pixel 106G, and the optical adjustment layer 116 is arranged in the pixel 106B. The optical adjustment layers 114 to 116 have different thicknesses (optical distances) in the pixels 106R, 106G, and 106B, respectively. Thus, due to the optical resonance effect, the color purity of light emitted from each of the pixels 106R, 106G, and 106B can be improved.

More specifically, by causing light emitted from the light emitting layer of the organic compound layer 111 to resonate between the reflective layer 117 and the upper electrode 110, light of a desired resonant wavelength can be extracted. The resonant wavelength satisfies the following equation as a function of an optical distance L₀ of the optical adjustment layers 114 to 116, a resonant wavelength λ₀, and a total phase shift Φ by multiple reflection.

$$[ ( 2 \times {L}_{0} ) / {λ}_{0} + Φ ] / ( 2 π ) = {m}_{0} ( {m}_{0} is an integer )$$

A so-called silicon oxide material such as silicon nitride, silicon oxynitride, or silicon oxide can be used for the optical adjustment layers 114 to 116.

In the configuration shown in FIG. 3A, the light emitting layer of the organic compound layer 111 emits light of the same color in the pixels 106R, 106G, and 106B. To the contrary, by changing the thicknesses of the optical adjustment layers 114 to 116 for the respective pixels 106, it is possible to extract light of a desired resonant wavelength. As shown in FIG. 3A, by sharing the organic compound layer 111 by the respective pixels 106, the cumbersome of manufacturing can be suppressed to improve reliability, as compared with a case where the organic compound layer 111 is formed for each color. This can be advantageous in miniaturizing the pixels 106, as compared with a case where the organic compound layer 111 is formed for each color.

The wiring structure 118 can be arranged between the substrate 119 and the reflective layer 117. In the wiring structure 118, a wiring pattern or the like for connecting transistors arranged on the substrate 119 or the light emitting element 105 and a circuit such as a transistor arranged on the substrate 119 can be arranged. The wiring structure 118 can be, for example, a multilayer wiring structure obtained by arranging a conductive pattern using aluminum, copper, or the like in an insulating layer of silicon nitride, silicon oxynitride, silicon oxide, or the like.

For example, a semiconductor material such as silicon can be used for the substrate 119. However, the present disclosure is not limited to this, and a semiconductor layer may be arranged as the substrate 119 on an insulating substrate such as glass. As described above, a circuit including a transistor is provided on the substrate 119.

Next, the effect of this embodiment will be described. A solid line shown in the sectional view of FIG. 1A indicates a light beam emitted in a desired direction due to desired optical interference. On the other hand, a broken line indicates a light beam emitted in an oblique direction due to optical interference different from desired one. In the light emitting device 100, the optical distance L₀ can be designed so that strong light of the wavelength 2 is extracted in a direction (normal direction) perpendicular to the main surface 151 of the substrate 119. In this case, light emitted obliquely with respect to the substrate 119 deviates from a desired resonant (interference) condition, thereby lowering color purity. If light with low color purity is emitted from the light emitting device 100, the color gamut of the light emitting device 100 is reduced.

For example, due to the request of an optical system installed outside the light emitting device 100 (for example, an optical system arranged on the low refractive index layer 101), it may be necessary to extract strong light in a direction inclined with respect to the normal direction of the main surface 151 of the substrate 119. In this case, as shown in FIGS. 1A and 1B, it can be designed to extract strong light in an oblique direction by arranging the vertex C1 of the microlens 102 and the geometric centroid C3 of the light emitting region 104 while shifting them. In this case, as compared with a case where light is extracted in the normal direction of the main surface 151 of the substrate 119, a light beam of shifted optical interference is readily mixed to cause color misregistration.

The light beam of the broken line shown in FIG. 1A deteriorates in color purity due to an optical path length different from the desired optical interference distance, as compared with the light beam of the solid line. A part (the light beam of the solid line) of light emitted from the light emitting region 104 of the light emitting element 105 enters the microlens 102, is refracted by the interface between the microlens 102 and the low refractive index layer 101, and exits from the microlens 102. On the other hand, the light beam with low color purity, which is emitted from the light emitting region 104 in the oblique direction and indicated by the broken line, is shielded by the light shielding layer 103. This suppresses light with low color purity from being emitted from the light emitting device 100, thereby suppressing reduction of the color gamut.

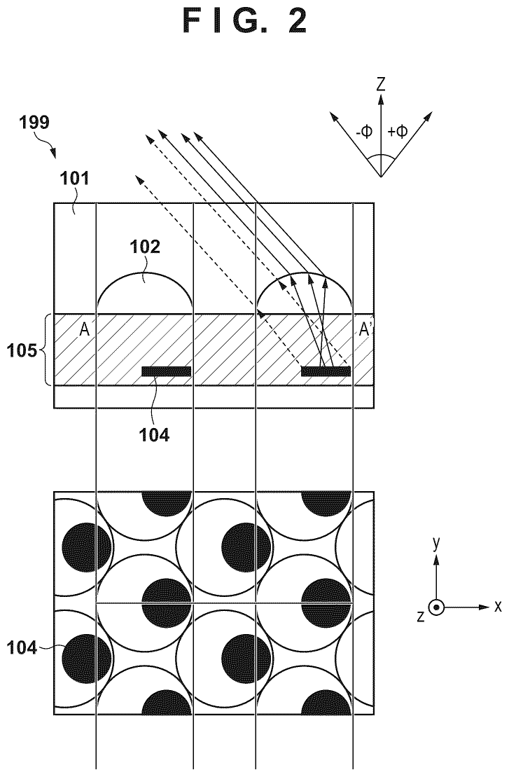

FIG. 2 shows a light emitting device 199 in which no light shielding layer 103 is arranged according to a comparative example. As shown in FIG. 2, in a case where no light shielding layer 103 is arranged, a light beam with low color purity, which is emitted from the light emitting region 104 in an oblique direction and indicated by a broken line is emitted from the light emitting device 199. This may reduce the color gamut. By arranging the light shielding layer 103, the light emitting device 100 according to this embodiment can suppress radiation of light with low color purity, thereby improving the display quality of the light emitting device 100.

As shown in FIG. 1B, in the pixel 106 arranged in the light emitting device 100 of this embodiment, the vertex C1 of the microlens 102 and the geometric centroid C3 of the light emitting region 104 are arranged at different positions in the orthogonal projection to the main surface 151 of the substrate 119. Furthermore, in the pixel 106, the distance between the geometric centroid C3 of the light emitting region 104 and the geometric centroid C2 of the opening portion 107 provided in the light shielding layer 103 is shorter than the distance between the vertex C1 of the microlens 102 and the geometric centroid C3 of the light emitting region 104. In the orthogonal projection to the main surface 151 of the substrate 119, the geometric centroid C2 of the opening portion 107 may be arranged between the vertex C1 of the microlens 102 and the geometric centroid C3 of the light emitting region 104. In this case, as shown in FIG. 1B, in the orthogonal projection to the main surface 151 of the substrate 119, the vertex C1 of the microlens 102, the geometric centroid C2 of the opening portion 107, and the geometric centroid C3 of the light emitting region 104 may be arranged on a virtual straight line. Thus, it is possible to extract light of a desired resonant wavelength from the light emitting device 100, and effectively shield, by the light shielding layer 103, light with low color purity that satisfies an interference condition different from a desired one.

In the configuration shown in FIG. 3A, it has been described that light of a desired wavelength is extracted by arranging the optical adjustment layers 114 to 116. However, as shown in FIG. 3B, even in a case where the optical adjustment layers 114 to 116 are arranged, color filters 123 to 125 may be arranged. In the light emitting element 105 shown in FIG. 3B, the color filters 123 to 125 and an upper planarizing layer 126 are arranged in addition to the configuration shown in FIG. 3A. On the upper planarizing layer 126, for example, the microlens 102 is arranged in contact with the upper planarizing layer 126.

In the configuration shown in FIG. 3B, it is possible to extract light of a desired resonant wavelength from each of the pixels 106R, 106G, and 106B, similar to the configuration shown in FIG. 3A. Therefore, as compared with a case where no optical adjustment layers 114 to 116 are arranged, thin films or color filters with low color material concentration and high transmittance can be used as the color filters 123 to 125. Therefore, it is possible to suppress a decrease in luminance caused by arranging the color filters 123 to 125.

The color filters 123 to 125 are color filters having different transmission spectral characteristics. For example, the color filter 123 arranged in the pixel 106R transmits red light. Similarly, the color filter 124 arranged in the pixel 106G transmits green light, and the color filter 125 arranged in the pixel 106B transmits blue light. However, the present disclosure is not limited to this, for example, color filters that transmit cyan, yellow, and magenta light beams, respectively, may be combined.

To form the color filters 123 to 125, liquid color resist composed of a color material, dispersant, resin, additive, solvent, or the like can be used. A color material that mainly decides the spectral characteristic of each color filter may be obtained by adding a plurality of pigments or dyes. First, a color resist is applied and deposited using the spin coating method, the inkjet method, or the like. Next, patterning is performed using the photolithography method or the like, thereby forming a color filter. Deposition and patterning of the color resist are performed for each color, thereby forming a color filter layer formed by the color filters 123 to 125 of the plurality of colors. Some or all of the color filters can be omitted. As shown in FIG. 3B, the film thicknesses of the color filters 123 to 125 need not always the same for the respective colors. Thus, the surface of the color filter layer formed by the color filters 123 to 125 may have unevenness.

The upper planarizing layer 126 can be formed to planarize the unevenness of the surface of the color filter layer. By adjusting the film thickness of the upper planarizing layer 126, the film thickness of the planarizing layer 108, or both of them, it is possible to adjust the focal position of the microlens 102 and the position of the light emitting region 104. To form the upper planarizing layer 126, a liquid white resist composed of a resin, additive, solvent, or the like can be used. As the resin, acrylic resin, epoxy resin, PHS resin, novolac resin, or the like can be used. The upper planarizing layer 126 may be formed by applying the white resist using the spin coating method or the inkjet method, and curing it. The upper planarizing layer 126 need not be formed. If, for example, the unevenness of the surface of the color filter layer formed by the color filters 123 to 125 is small, the upper planarizing layer 126 need not be arranged.

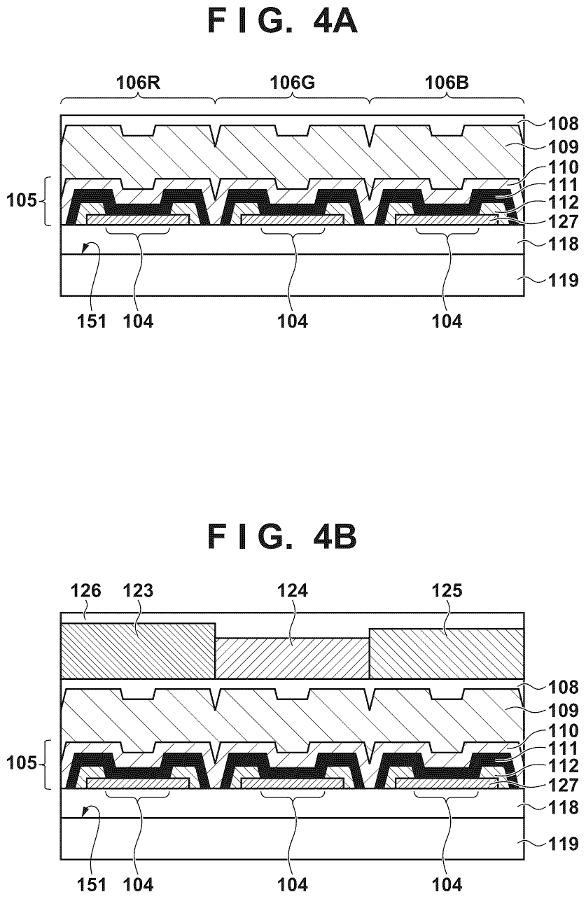

A modification of the light emitting element 105 will be described next with reference to FIG. 4A. It has been described above that the organic compound layer 111 (light emitting layer) is common to the pixels 106R, 106G, and 106B and the optical adjustment layers 114 to 116 and the reflective layer 117 are used to extract light of a desired resonant wavelength. However, the light emitting element 105 used for the light emitting device 100 according to this embodiment is not limited to the structure including the optical adjustment layers 114 to 116 and the reflective layer 117.

In the configuration shown in FIG. 4A, the optical adjustment layers 114 to 116 and the reflective layer 117 are not arranged. On the other hand, in each of the pixels 106R, 106G, and 106B, the organic compound layer 111 is separately arranged. Thus, in the configuration shown in FIG. 4A, the organic compound layer 111 (light emitting layer) emits light of a different color for each of the pixels 106R, 106G, and 106B. That is, it is possible to extract light of a desired wavelength from each of the pixels 106R, 106G, and 106B. In the configuration shown in FIG. 4A, the light emitting layer arranged in each organic compound layer 111 emits each color, and thus no color filter is required. Therefore, light is not absorbed by the color filter, thereby making it possible to improve luminance.

In the configuration shown in FIG. 4A, a lower electrode 127 need not transmit light to the side of the substrate 119, unlike the lower electrode 113 shown in FIG. 3A. Therefore, for example, a material having a refractive index of 70% or more with respect to light emitted from the light emitting layer of the organic compound layer 111 may be used for the lower electrode 127. A metal such as aluminum or silver, an alloy thereof added with silicon, copper, nickel, neodymium, or the like, a transparent oxide film of ITO, IZO, or the like, or a multilayered film thereof can be used as the lower electrode 127.

In the configuration shown in FIG. 4A, optical resonance (interference) occurs in accordance with the optical distance between the upper electrode 110 and the lower electrode 127 but there is no difference in occurrence status among the pixels 106R, 106G, and 106B. On the other hand, as described above, light emitted in the normal direction of the main surface 151 of the substrate 119 has desired color purity but light emitted in an oblique direction may deteriorate in color purity. As described above, this is because in the light emitting device 100, the pixel 106 can optimally be designed with respect to light extracted in the normal direction of the main surface 151 of the substrate 119. Therefore, with respect to the light emitting element 105 shown in FIG. 4A as well, the light shielding layer 103 shown in FIG. 1A shields light with low color purity emitted in an oblique direction. Thus, it is possible to suppress reduction of the color gamut of the light emitting device 100 and improve display quality.

FIG. 4B is a view showing a modification of the light emitting element 105 shown in FIG. 4A. Similar to the light emitting element 105 shown in FIG. 3B with respect to the light emitting element 105 shown in FIG. 3A, the color filters 123 to 125 and the upper planarizing layer 126 are arranged in the light emitting element shown in FIG. 4B, in addition to the configuration shown in FIG. 4A.

In the configuration shown in FIG. 4B, it is possible to extract light of a desired wavelength from each of the pixels 106R, 106G, and 106B, similar to the configuration shown in FIG. 4A. Therefore, as compared with a case where the organic compound layer 111 emits light (for example, white light) of the same color, thin films or color filters with low color material concentration and high transmittance can be used as the color filters 123 to 125. Therefore, it is possible to suppress a decrease in luminance caused by arranging the color filters 123 to 125. Due to the spectral effect of the color filters 123 to 125, it is possible to implement the light emitting device 100 with high color purity and a high color gamut, as compared with the configuration shown in FIG. 4A.

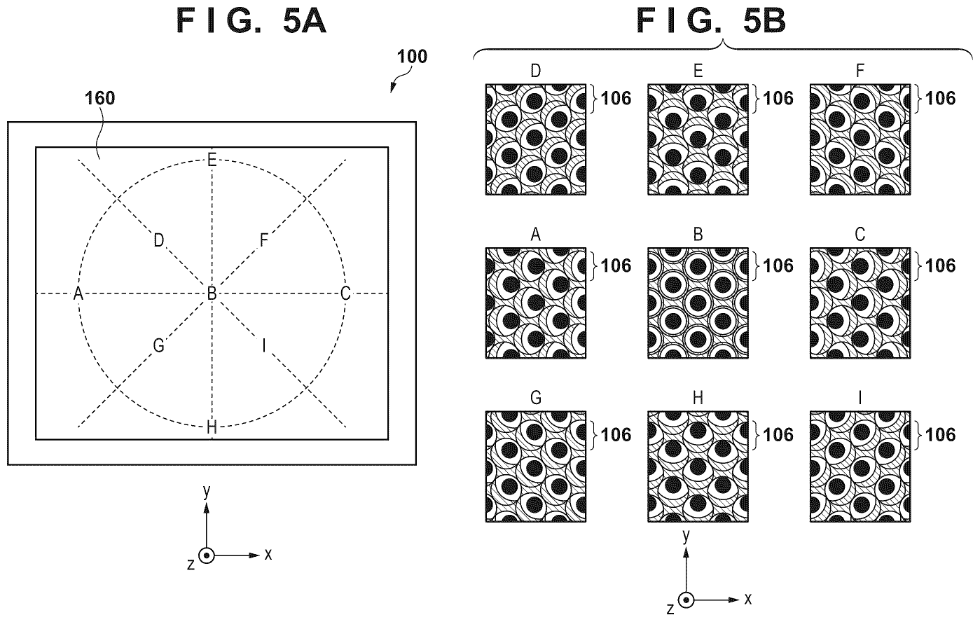

The light emitting device 100 according to this embodiment will be described next with reference to FIGS. 5 to 7. As described above, the light emitting device 100 can include a display region 160 where the plurality of pixels 106 are arranged. The arrangement of the microlens 102, the light shielding layer 103, and the light emitting region 104 in each pixel 106 arranged in the display region 160 may be same for all the pixels 106. However, the present disclosure is not limited to this, and the arrangement of the microlens 102, the light shielding layer 103, and the light emitting region 104 in each pixel 106 may change in accordance with the arrangement position in the display region 160.

FIG. 5A shows the light emitting device 100 including the display region 160 where the plurality of pixels 106 are arranged. FIG. 5B is a schematic view of the pixels 106 in regions A to I of the display region 160. FIG. 5B shows the microlens 102, the light shielding layer 103, and the light emitting region 104 of each pixel 106 (for the sake of simplicity, reference numerals are omitted), similar to FIG. 1B. As shown in FIG. 5B, the plurality of pixels 106 are arrayed in a delta arrangement in the display region 160, but the present disclosure is not limited to this. The plurality of pixels may be arrayed in a stripe arrangement, a square arrangement, a pentile arrangement, a Bayer arrangement, or the like.

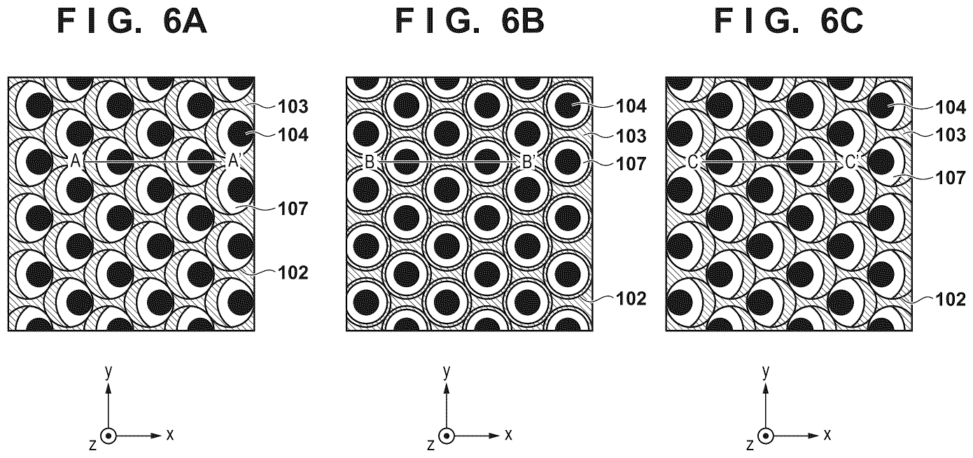

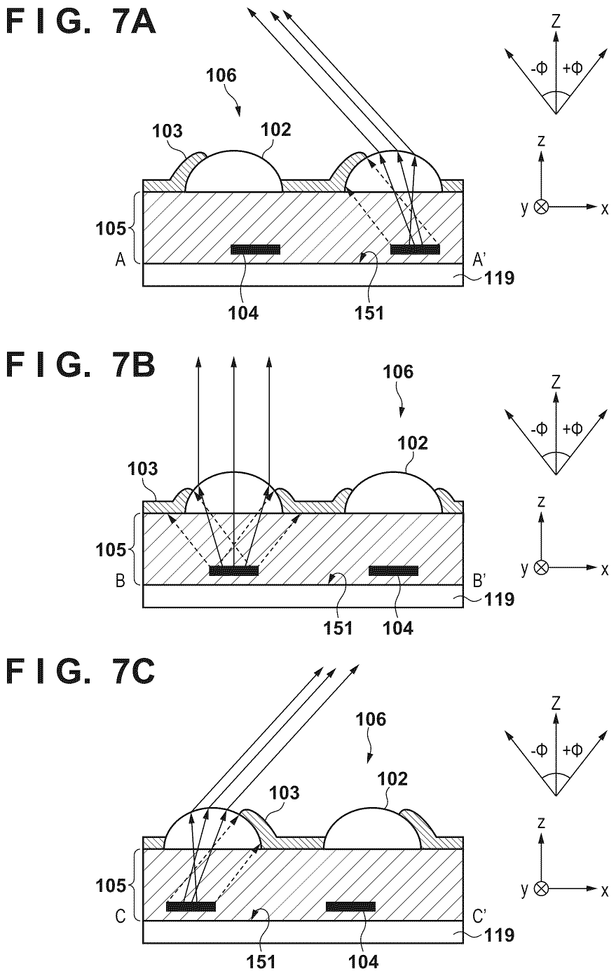

FIGS. 6A to 6C are plan views of the pixels 106 arranged in the regions A to C shown in FIGS. 5A and 5B. FIGS. 7A to 7C are sectional views taken along lines A-A′, B-B′, and C-C′ in FIGS. 6A to 6C, respectively.

FIGS. 6B and 7B are schematic views of the pixels 106 near the center of the display region 160. As shown in FIGS. 6B and 7B, in the orthogonal projection to the main surface 151 of the substrate 119, in the pixel 106 arranged in the region B at the center of the display region 160 among the plurality of pixels 106, the vertex C1 of the microlens 102, the geometric centroid C2 of the opening portion 107 provided in the light shielding layer 103, and the geometric centroid C3 of the light emitting region 104 may be arranged at positions overlapping each other. As shown in FIG. 7B, the light shielding layer 103 can cover the outer edge portion of the microlens 102 by a predetermined width. This suppresses the light beam with low color purity, which is emitted from the light emitting region 104 in an oblique direction and indicated by the broken line, from being emitted from the light emitting device 100.

Furthermore, in each of the above-described configurations and following configurations, in the orthogonal projection to the main surface 151 of the substrate 119, the light shielding layer 103 is arranged to cover not only a part of each microlens 102 but also a space between the microlenses 102 of the plurality of pixels 106. Thus, it is possible to shield light emitted between the microlenses 102, as shown in FIG. 7B. Therefore, it is possible to suppress a deterioration in image quality caused by unexpected color mixture of light between the adjacent pixels 106.

As will be described later, the arrangement of the microlens 102, the opening portion 107, and the light emitting region 104 in the pixel 106 arranged in the display region 160 can continuously change. Therefore, in the orthogonal projection to the main surface 151 of the substrate 119, in the pixel 106 arranged at the center of the display region 160 among the plurality of pixels 106, the vertex C1 of the microlens 102, the geometric centroid C2 of the opening portion 107 provided in the light shielding layer 103, and the geometric centroid C3 of the light emitting region 104 may be arranged at positions overlapping each other. In at least one pixel 106 arranged at the center of the display region 160, the vertex C1 of the microlens 102, the geometric centroid C2 of the opening portion 107 provided in the light shielding layer 103, and the geometric centroid C3 of the light emitting region 104 can be arranged at positions overlapping each other. The plurality of pixels 106 arranged in the region B of the display region 160 may have the same arrangement.

FIGS. 6A and 7A are schematic views of the pixels 106 arranged in the region A near the left end (in the −x direction) of the display region 160. As shown in FIGS. 6A and 7A, in the orthogonal projection to the main surface 151 of the substrate 119, the vertex C1 of the microlens 102 shifts in the left direction (−x direction) with respect to the geometric centroid C3 of the light emitting region 104. As shown in FIG. 7A, the emission angle of the light beam with high color purity, which is a main light beam and indicated by the solid line, is on the wide angle side (−Φ), as compared with FIG. 7B. As shown in FIGS. 6A and 7A, as compared with the configuration shown in FIGS. 6B and 7B, the light shielding layer 103 widely covers the surface of the microlens 102 in the −Φ direction, and narrowly covers the surface of the microlens 102 in the +Φ direction. Therefore, the light beam with low color purity, which is indicated by the broken line, is shielded by the light shielding layer 103, thereby suppressing emission from the light emitting device 100.

FIGS. 6C and 7C are schematic views of the pixels 106 arranged in the region C near the right end (in the +x direction) of the display region 160. As shown in FIGS. 6C and 7C, in the orthogonal projection to the main surface 151 of the substrate 119, the vertex C1 of the microlens 102 shifts in the right direction (+x direction) with respect to the geometric centroid C3 of the light emitting region 104. As shown in FIG. 7C, the emission angle of the light beam with high color purity, which is a main light beam and indicated by the solid line, is on the wide angle side (+Φ), as compared with FIG. 7B. As shown in FIGS. 6C and 7C, as compared with the configuration shown in FIGS. 6B and 7B, the light shielding layer 103 widely covers the surface of the microlens 102 in the +Φ direction, and narrowly covers the surface of the microlens 102 in the −Φ direction. Therefore, the light beam with low color purity, which is indicated by the broken line, is shielded by the light shielding layer 103, thereby suppressing emission from the light emitting device 100.

As shown in FIGS. 5 to 7, in the orthogonal projection to the main surface 151 of the substrate 119, the geometric centroid C3 of the light emitting region 104 of the pixel 106 may be arranged between the center of the display region 160 and the vertex C1 of the microlens 102 of the pixel 106. Thus, when, in response to the request of the optical system outside the light emitting device 100 or the like, a light beam is extracted from the display region 160 in an enlarging direction, strong light can be extracted in accordance with each of the regions A to I of the display region 160. In this case, in the orthogonal projection to the main surface 151 of the substrate 119, the distance between the vertex C1 of the microlens 102 and the geometric centroid C3 of the light emitting region 104 in each of the plurality of pixels 106 may become longer continuously or stepwise as the distance from the center of the display region 160 is longer. In this case, in the orthogonal projection to the main surface 151 of the substrate 119, the distance between the vertex C1 of the microlens 102 and the geometric centroid of the opening portion 107 provided in the light shielding layer 103 in each of the plurality of pixels 106 may become longer continuously or stepwise as the distance from the center of the display region 160 is longer.

In this case, consider the relationship between a first pixel 106A arranged in the region A and a second pixel 106B arranged between the first pixel 106A and the center of the display region 160 among the plurality of pixels 106. In this case, in the orthogonal projection to the main surface 151 of the substrate 119, the distance between the vertex C1 of the microlens 102 and the geometric centroid C3 of the light emitting region 104 in the first pixel 106A can become longer than the distance between the vertex C1 of the microlens 102 and the geometric centroid C3 of the light emitting region 104 in the second pixel 106B. Furthermore, in the orthogonal projection to the main surface 151 of the substrate 119, the distance between the vertex C1 of the microlens 102 and the geometric centroid C2 of the opening portion 107 in the first pixel 106A can become longer than the distance between the vertex C1 of the microlens 102 and the geometric centroid C2 of the opening portion 107 in the second pixel 106B. In addition, as the distance from the center of the display region 160 is longer, an area of a portion of the microlens 102 covered by the light shielding layer 103 on a side opposite to a side facing the center of the display region 160 can become larger continuously or intermittently. Therefore, the shortest distance between the microlens 102 and the outer edge of the opening portion 107 in the first pixel 106A can be shorter than the shortest distance between the microlens 102 and the outer edge of the opening portion 107 in the second pixel 106B.

As described above, in the pixel 106 arranged at the center of the display region 160, the vertex C1 of the microlens 102, the geometric centroid C2 of the opening portion 107 provided in the light shielding layer 103, and the geometric centroid C3 of the light emitting region 104 can be arranged at positions overlapping each other. On the other hand, as shown in FIGS. 7A and 7B, the vertex C1 of the microlens 102 continuously or intermittently shifts outward toward the outer edge of the display region 160 with respect to the geometric centroid C3 of the light emitting region 104. Therefore, in the pixel 106 arranged in the region B near the center of the display region 160, the difference between the distance from the vertex C1 of the microlens 102 to the geometric centroid C2 of the opening portion 107 provided in the light shielding layer 103 and the distance from the geometric centroid C2 of the opening portion 107 to the geometric centroid C3 of the light emitting region 104 is small. On the other hand, in the pixel 106 arranged in a region separated from the center of the display region 160, the difference between the distance from the vertex C1 of the microlens 102 to the geometric centroid C2 of the opening portion 107 provided in the light shielding layer 103 and the distance from the geometric centroid C2 of the opening portion 107 to the geometric centroid C3 of the light emitting region 104 can be large. In this case, as shown in FIG. 1B, in the orthogonal projection to the main surface 151 of the substrate 119, the distance between the vertex C1 of the microlens 102 and the geometric centroid C2 of the opening portion 107 may be shorter than the distance between the geometric centroid C2 of the opening portion 107 and the geometric centroid C3 of the light emitting region 104.

As described above, in this embodiment, the light shielding layer 103 covers a part of the microlens 102. As shown in FIGS. 5 to 7, the light shielding layer 103 widely covers the surface of the microlens 102 on the side of the emission direction of the main light beam in each of the regions A to I, and narrowly covers the surface on the opposite side of the emission direction of the main light beam. Thus, the light beam with low color purity is shielded by the light shielding layer 103, and it is possible to implement the light emitting device 100 with high color purity and a wide color gamut.

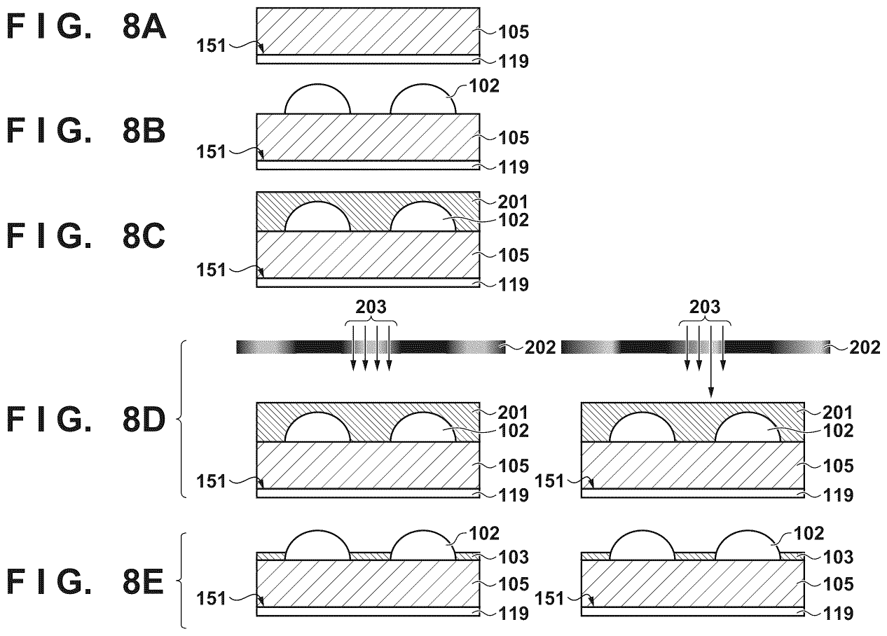

A manufacturing method of the above-described light emitting device 100 will be described next with reference to FIGS. 8A to 8E. First, a circuit for causing the pixel 106 including a transistor to operate (emit light) is formed on the substrate 119 using silicon or the like. Next, as shown in FIG. 8A, the above-described light emitting element 105 is formed on the main surface 151 of the substrate 119. The light emitting element 105 can have any of the above-described configurations shown in FIGS. 3A, 3B, 4A, and 4B, and the like. However, the present disclosure is not limited to this, and the light emitting element 105 may have a configuration different from those shown in FIGS. 3A, 3B, 4A, and 4B, and the like.

Next, as shown in FIG. 8B, the microlenses 102 are formed. As described above, the microlenses 102 can be formed using the thermal flow method, the etch back method, the gray tone mask method, or the like. In the configuration shown in FIG. 8B, an array of the spherical microlenses 102 with a gap therebetween is shown. However, the microlens array in which the plurality of microlenses 102 are arranged may be a gapless microlens array without any gap between the microlenses 102. The surface of the microlens 102 may be aspherical.

After the formation of the microlenses 102, a black resist film 201 that serves as the light shielding layer 103 is formed to cover the entire surface on the substrate 119, as shown in FIG. 8C. The black resist film 201 is a photosensitive resin film containing a black pigment, and can be deposited using the spin coating method or the inkjet method. In this embodiment, a black resist having sensitivity to negative i-line (a wavelength of 365 nm) is used, but a black resist may have sensitivity to positive i-line or may have sensitivity to another wavelength.

FIG. 8D shows a step of selectivity exposing the black resist film 201. An i-line stepper is used as an exposure device and a gray tone mask 202 is used as a photomask. The gray tone mask 202 can locally control the transmittance of the exposure light 203 (i-line in this embodiment) by appropriately designing a mask pattern, and form the light shielding layer 103 of a desired shape after development. A view on the left side of FIG. 8D is a schematic view of a position corresponding to FIG. 7B, and a view on the right side is a schematic view of a position corresponding to FIG. 7A.

In the gray tone mask 202, different patterns are arranged in accordance with the regions A to I and the like. For example, with one photomask (gray tone mask 202), the light shielding layer 103 of the entire display region 160 may be patterned. Although the gray tone mask 202 is formed by fine patterns (for example, fine dot patterns) of the resolution limit or less of the exposure device, the light shielding pattern of the light shielding layer 103 formed in each region of the display region 160 is controlled by changing the array of the fine patterns for each pixel 106. Thus, it is unnecessary to individually create a mask for each region, thereby suppressing, for example, an increase in manufacturing cost.

After the exposure step, a development step is performed to form the light shielding layer 103, as shown in FIG. 8E. For example, the substrate (the structure including the substrate 119, the light emitting element 105 formed on the substrate 119, the microlenses 102, and the black resist film 201) obtained after the exposure step is immersed in an alkaline developer to develop the black resist film 201, thereby forming the light shielding layer 103 of a desired shape. With the above steps, the light emitting device 100 according to this embodiment is formed.

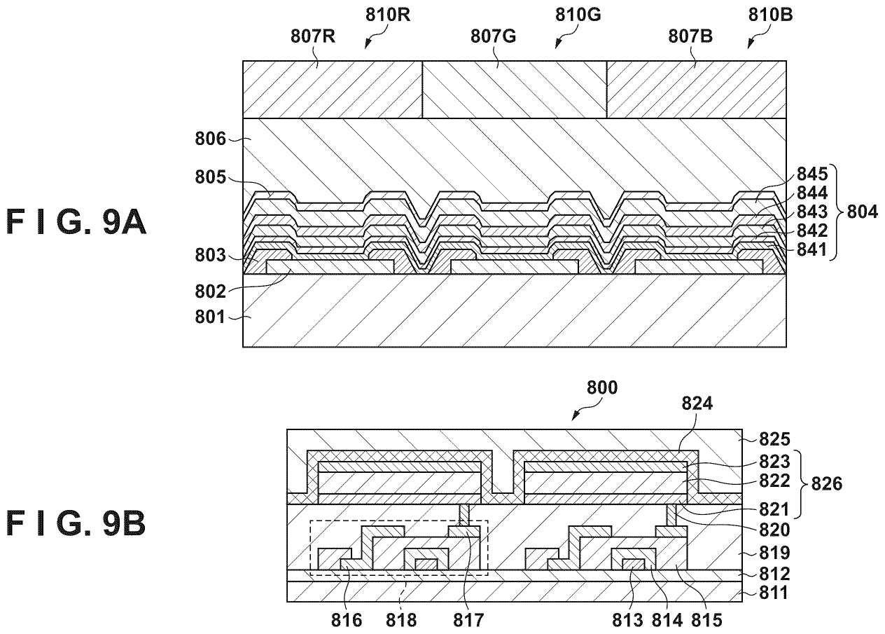

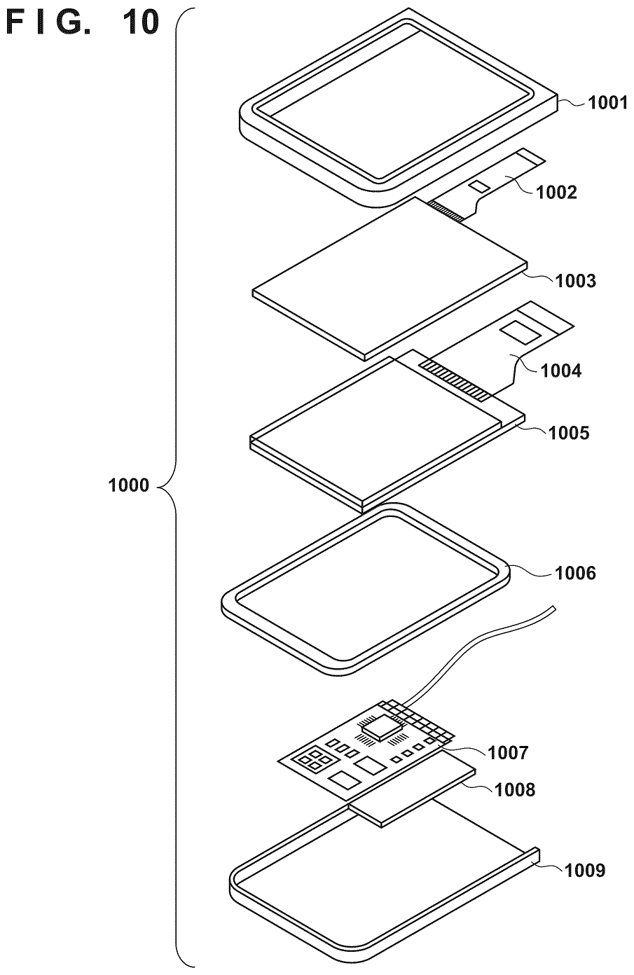

Application examples in which the light emitting device 100 according to this embodiment is applied to an image forming device, a display device, a photoelectric conversion device, an electronic apparatus, an illumination device, a moving body, and a wearable device will now be described with reference to FIGS. 9A to 15B. The description will be given assuming that, for example, an organic light emitting element (OLED) (corresponding to the above-described light emitting element 105) such as an organic EL element using an organic light emitting material is arranged in the pixel 106 (to be sometimes referred to as the pixel or the sub-pixel) arranged in the light emitting device 100. Details of each component arranged in the pixel 106 (light emitting element 105) of the above-described light emitting device 100 will be described first, and the application examples will be described after that.

The organic light emitting element according to an embodiment of the present disclosure includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by a plurality of layers as long as it includes a light emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from a plurality of layers. If the light emitting layer includes a plurality of layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by dissolving the compound to be measured in a solvent such as toluene and irradiating it with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a DMF solution of 0.1 M tetrabutylammonium perchlorate using a reference electrode of Ag/Ag⁺, a counter electrode of Pt, and a working electrode of glassy carbon. The LUMO can be estimated by adding −4.8 eV to the difference between the reduction potential of the obtained compound and that of ferrocene.

If the organic compound according to this embodiment is contained in the light emitting layer, the light emitting layer may be a layer made of only the organic compound according to this embodiment or a layer made of the organic metal complex according to this embodiment and another compound. Here, if the light emitting layer is a layer made of the organic metal complex according to this embodiment and another compound, the organic compound according to this embodiment may be used as a host or a guest of the light emitting layer. Alternatively, the organic compound may be used as an assist material that can be contained in the light emitting layer. Here, the host is a compound whose mass ratio is largest in the compounds forming the light emitting layer. The guest is a compound whose mass ratio is smaller than that of the host in the compounds forming the light emitting layer, and is a compound responsible for main light emission. The assist material is a compound whose mass ratio is smaller than that of the host in the compounds forming the light emitting layer, and which assists light emission of the guest. Note that the assist material is also called a second host. The host material can be called a first compound, and the assist material as a second compound.

If the organic compound according to an embodiment is used as the guest of the light emitting layer, the concentration of the guest may be 0.01 mass % (inclusive) to 20 mass % (inclusive) relative to the entire light emitting layer, or may be 0.1 mass % (inclusive) to 10 mass % (inclusive). The guest is also called a dopant.

The organic metal complex according to this embodiment can be used as the constituent material of the organic compound layer other than the light emitting layer forming the organic light emitting element according to this embodiment. More specifically, the organic metal complex may be used as the constituent material of an electron transport layer, an electron injection layer, a hole transport layer, a hole injection layer, a hole blocking layer, or the like. In this case, the light emission color of the organic light emitting element is not limited to red. More specifically, it may be white or an intermediate color.

A conventionally known low molecular and high molecular hole injection compound or hole transport compound, a compound serving as a host, a light emitting compound, an electron injection compound or electron transport compound, or the like can be used together as needed. Examples of these compounds will be described below.

As a hole injection/transport material, a material that has a high hole mobility such that hole injection from the anode is facilitated, and injected holes can be transported to the light emitting layer can suitably be used. Also, a material having a high glass transition point temperature can suitably be used to reduce degradation of film quality such as crystallization in the organic light emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

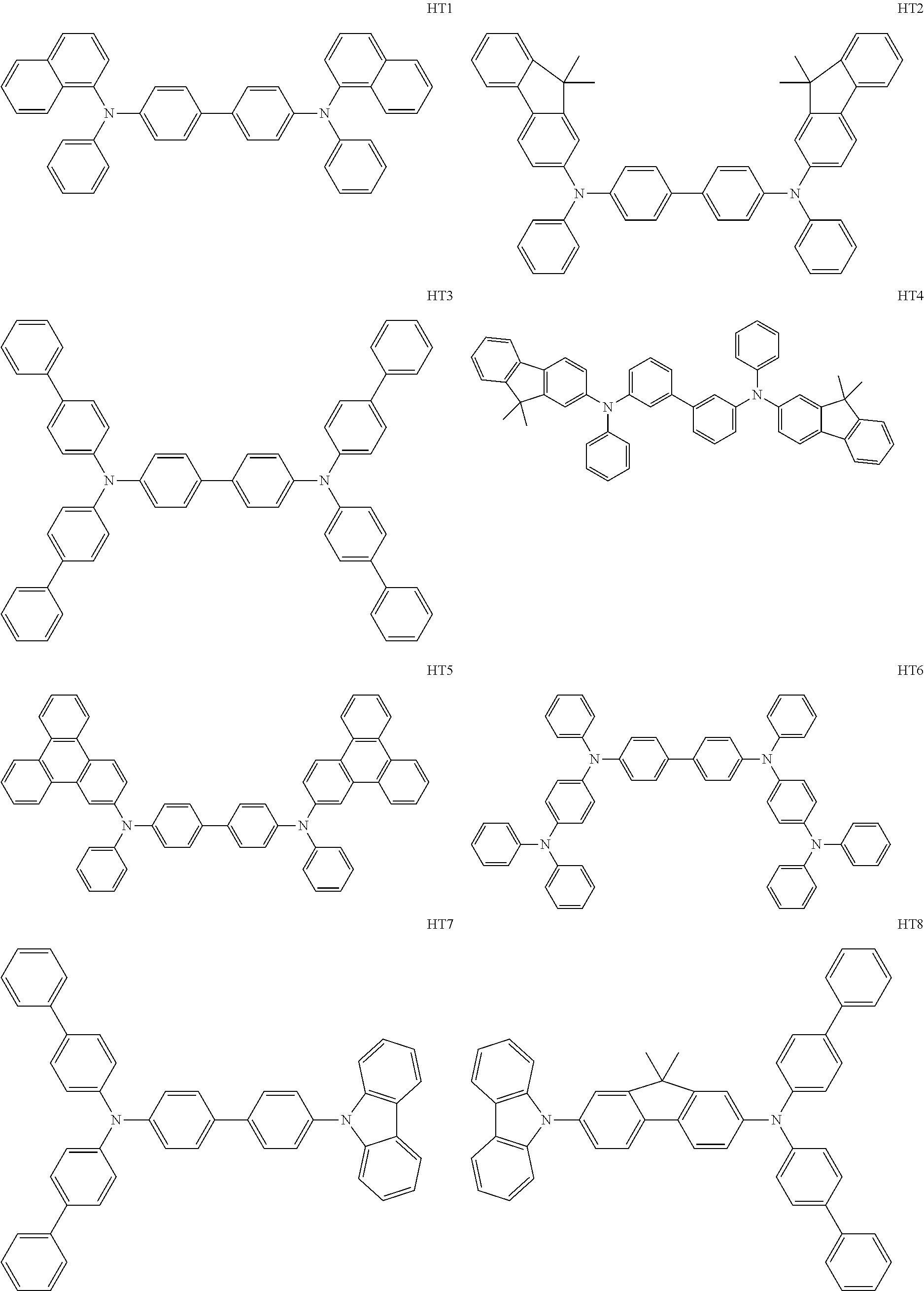

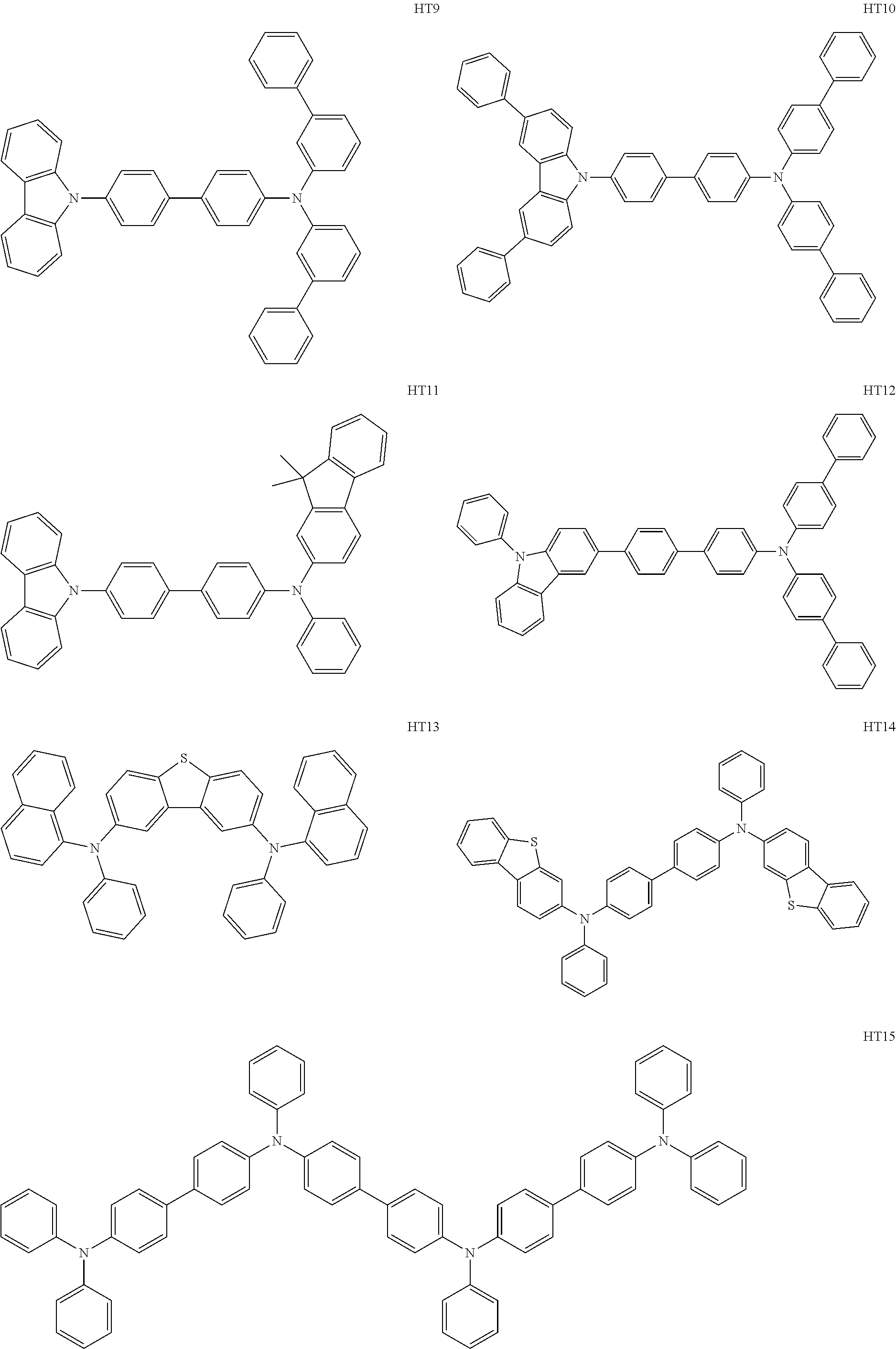

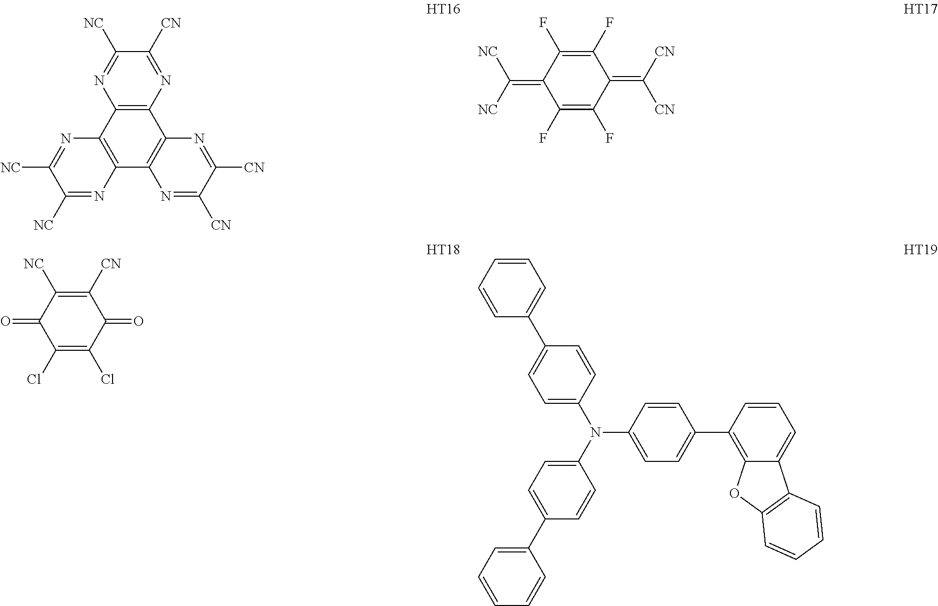

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these.

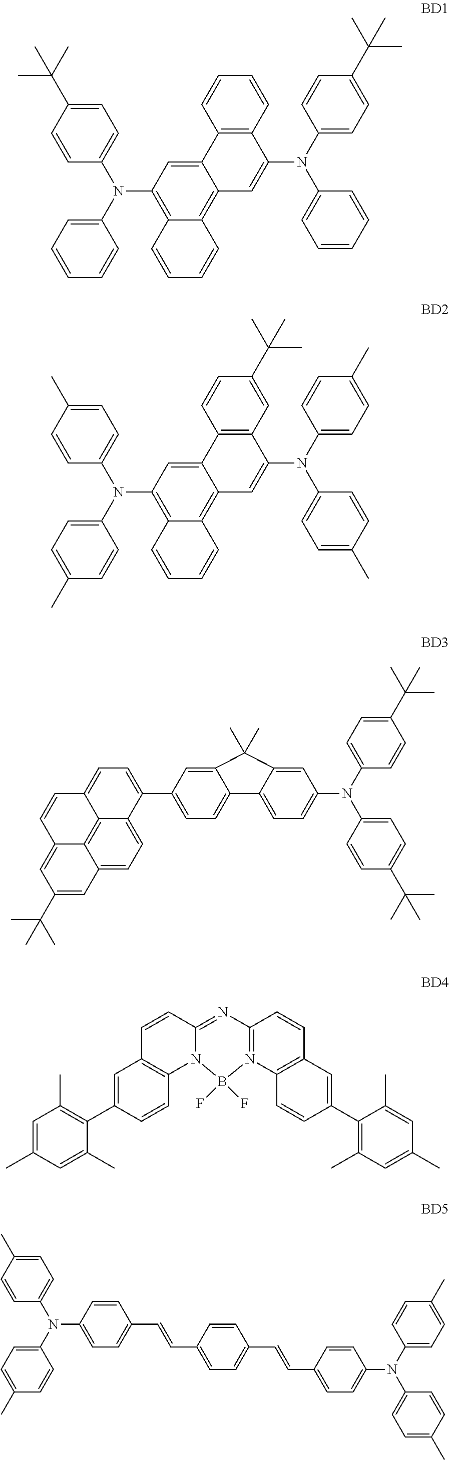

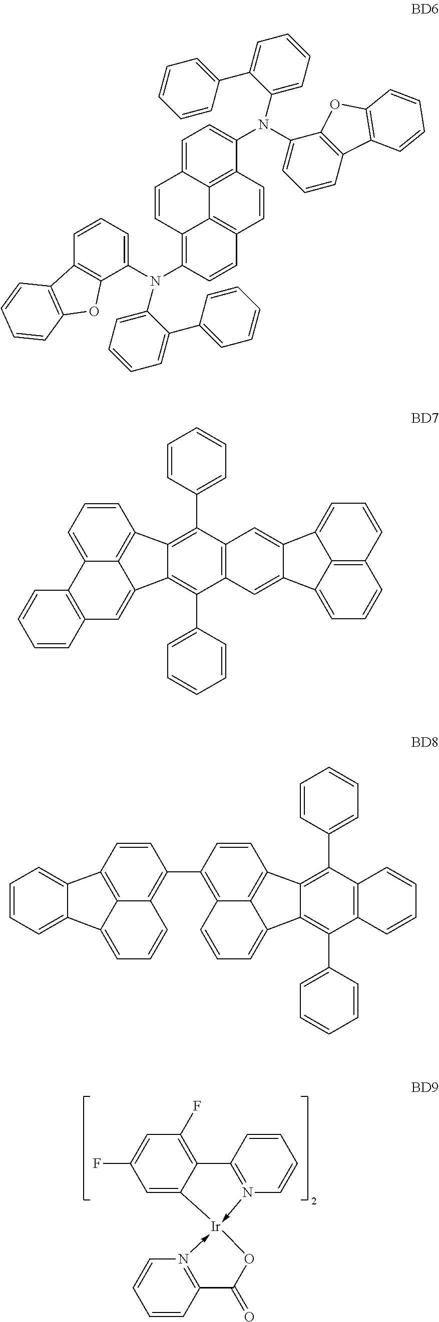

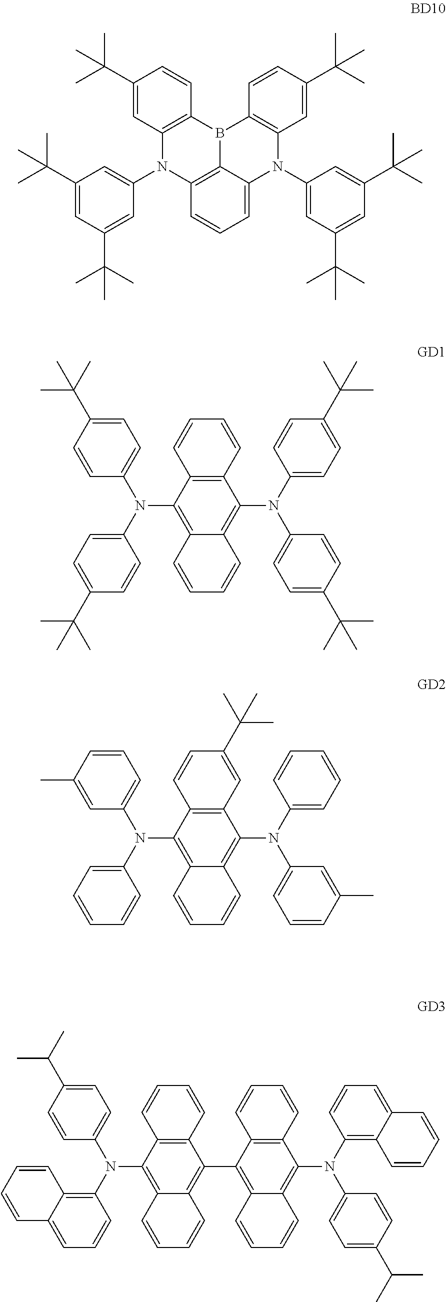

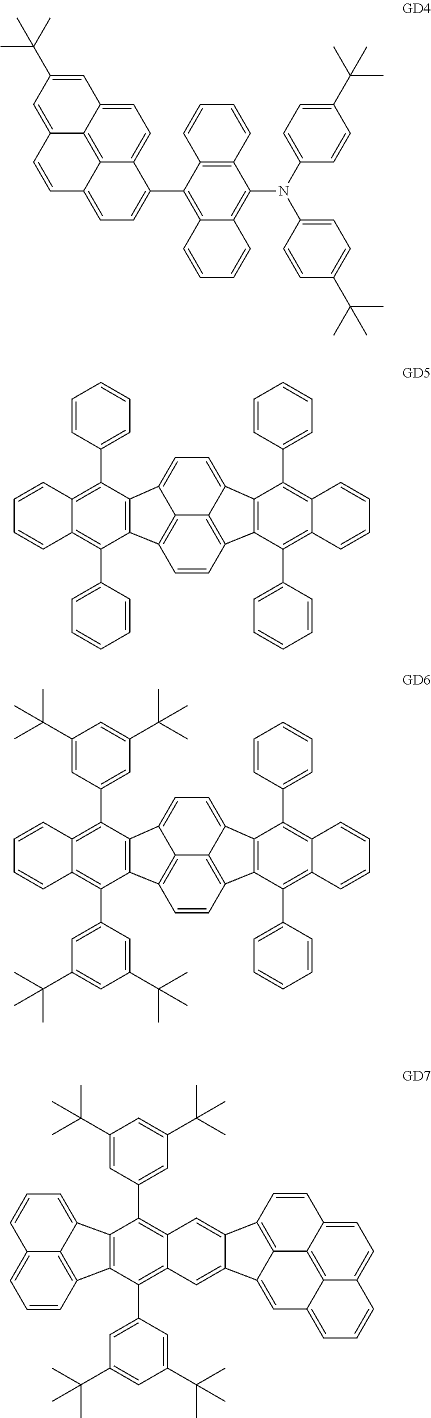

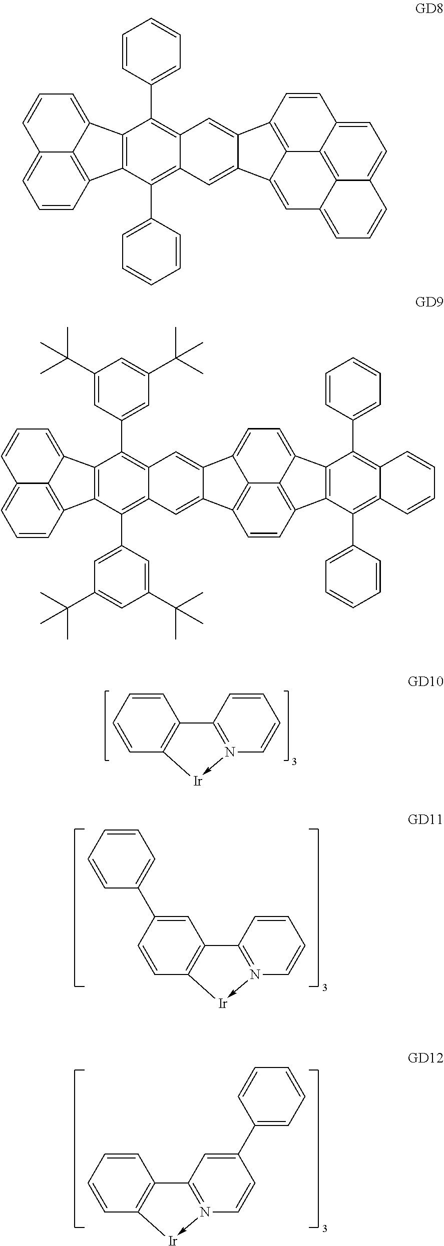

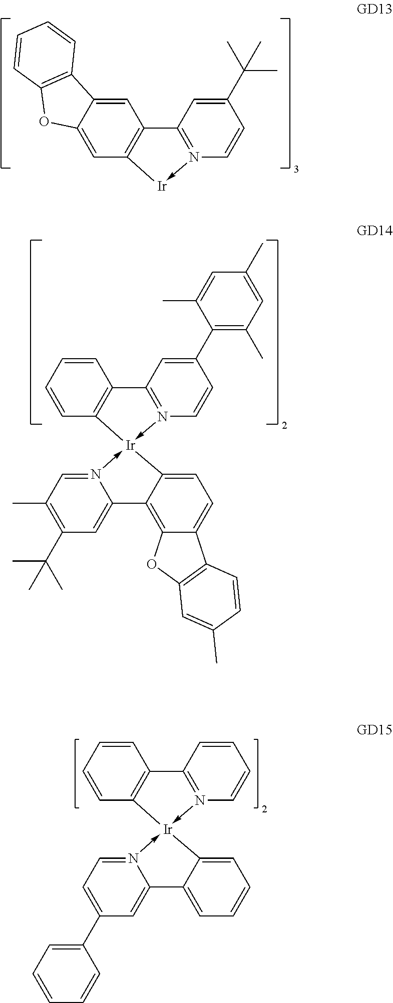

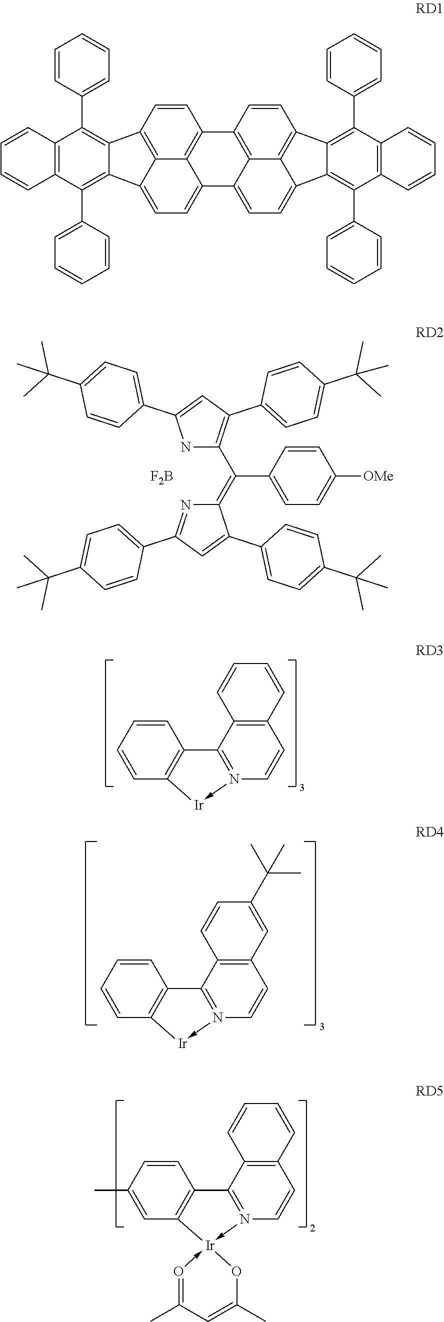

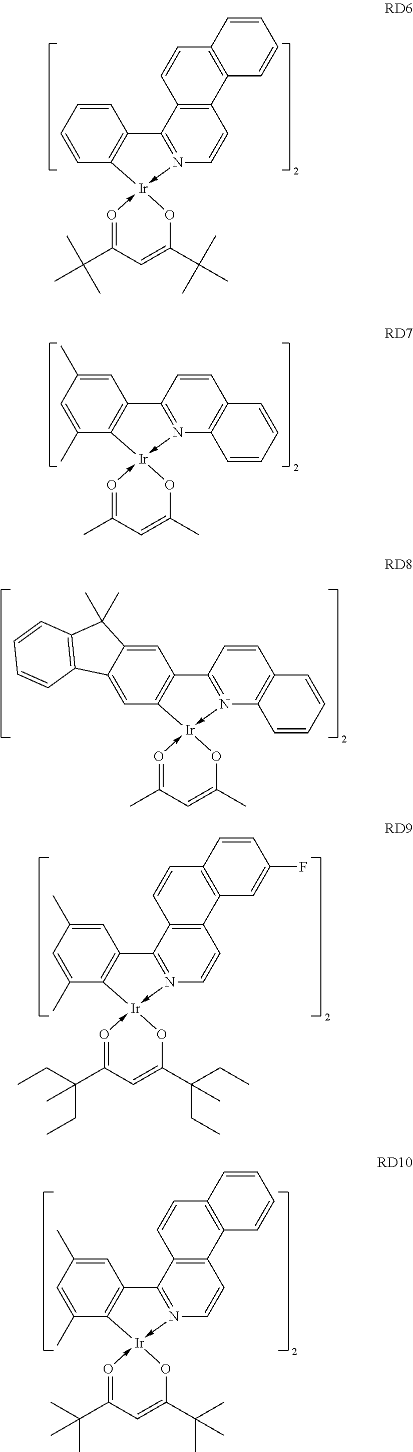

If the light emitting material is a hydrocarbon compound, this is suitable because it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, this is suitable because oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these.

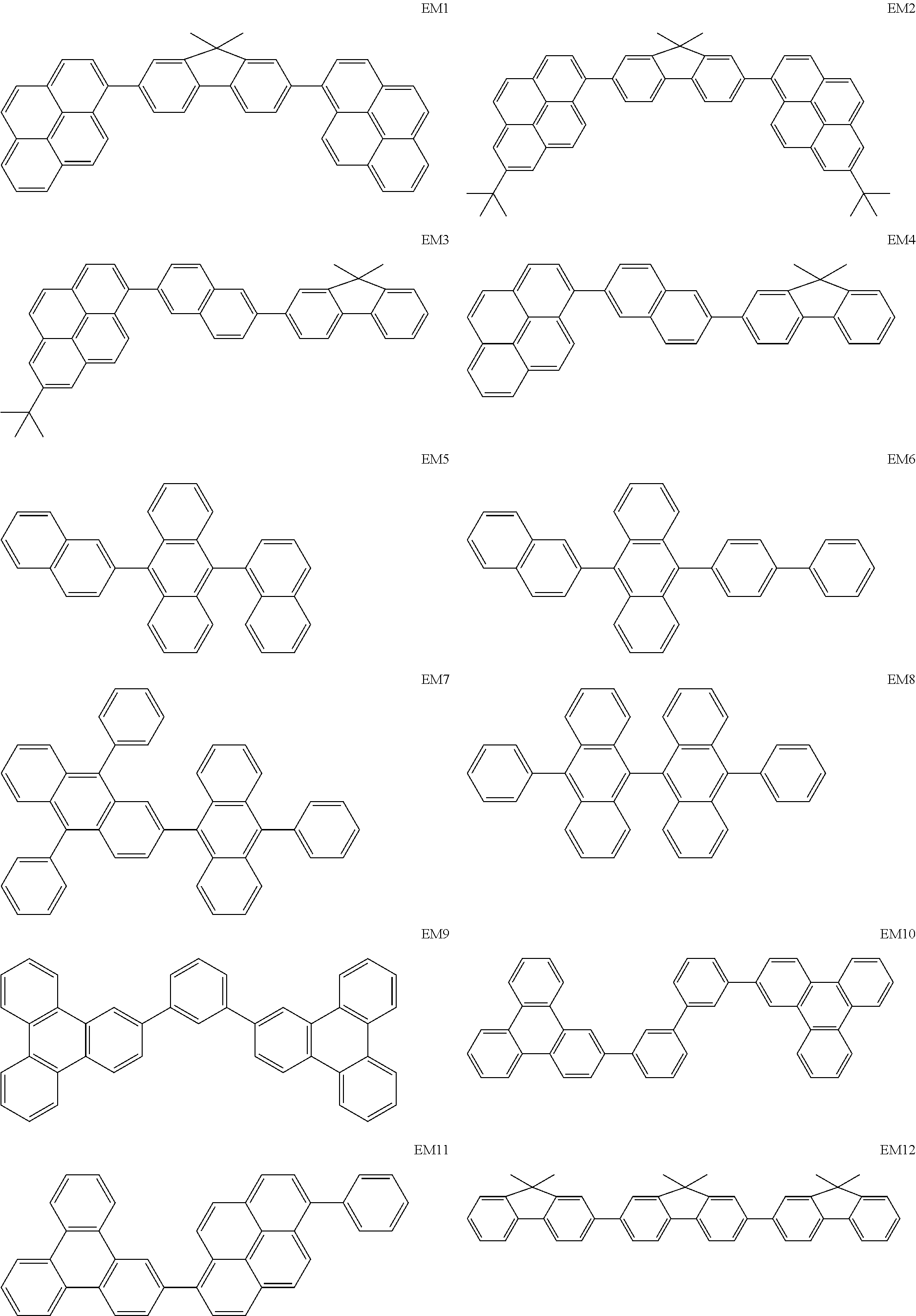

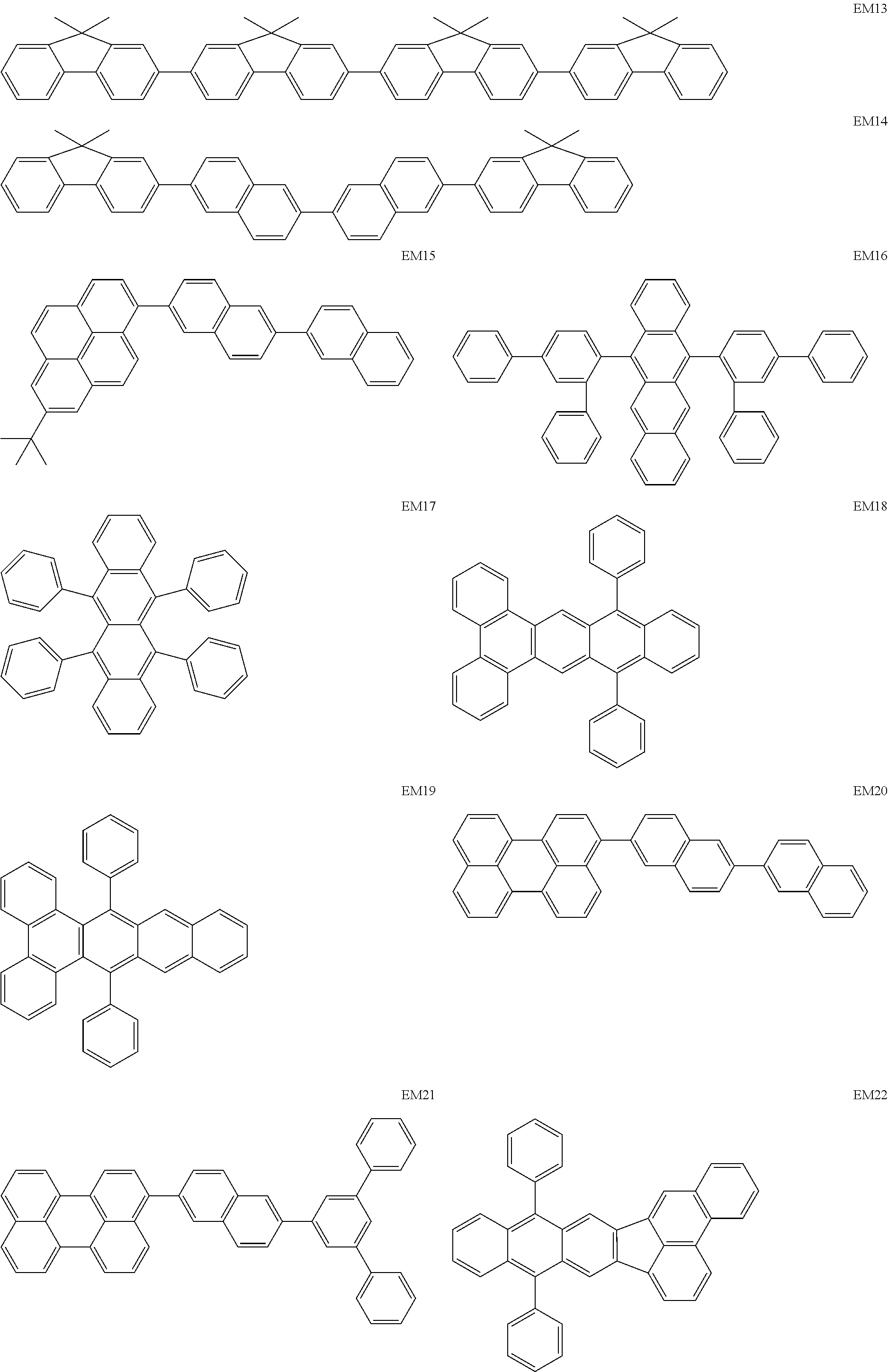

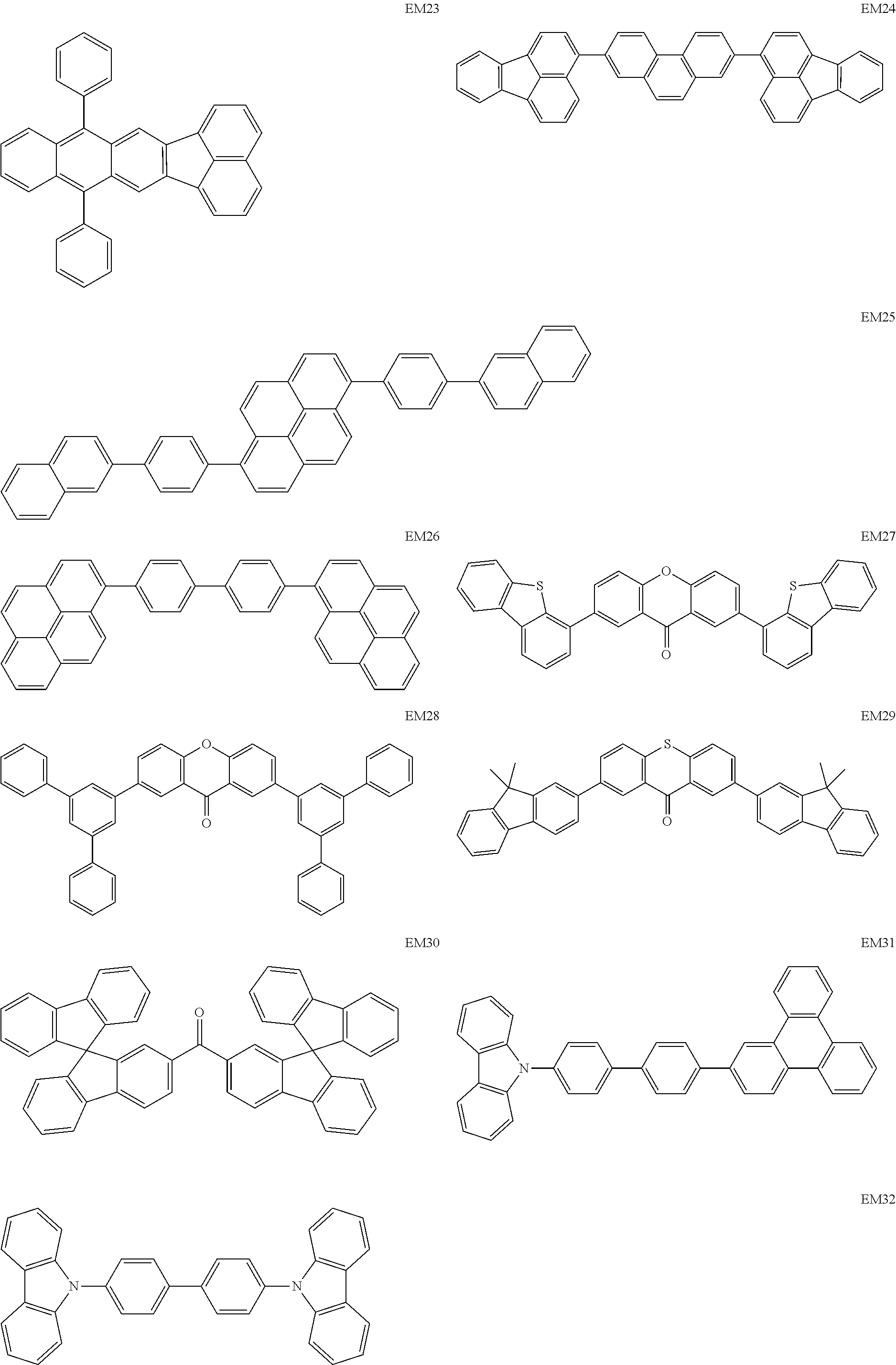

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material can also be used for the hole blocking layer as well.

Detailed examples of compounds used as the electron transport material will be shown below. The material is not limited to these.

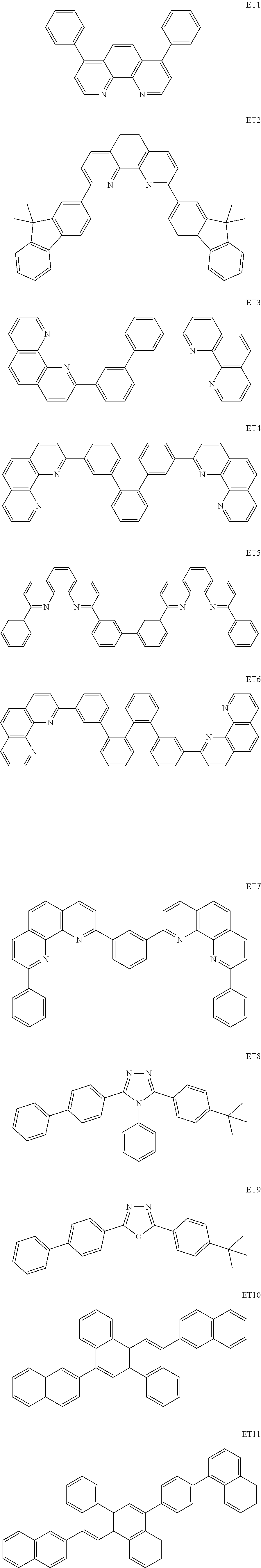

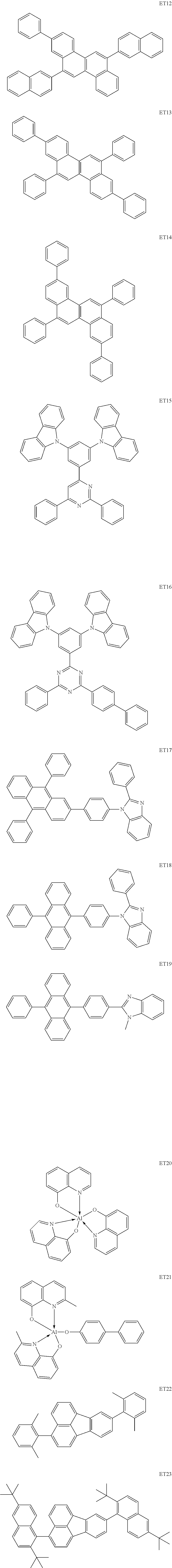

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present disclosure is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes. If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generating portion is provided between the second light emitting layer and the third light emitting layer.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 9A shows an example of the pixel arranged in the light emitting device 100. The pixel includes sub-pixels 810. The sub-pixels are divided into sub-pixels 810R, 810G, and 810B by light emission colors. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A light emitting device 800 shown in FIG. 9B is provided with an organic light emitting element 826 as an example of a light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 9B. That is, one of the anode and cathode and one of the source electrode and drain electrode of the TFT are electrically connected. The TFT indicates a thin-film transistor.

In the light emitting device 800 shown in FIG. 9B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the light emitting device 800 shown in FIG. 9B, but another switching element may be used instead.

The transistor used in the light emitting device 800 shown in FIG. 9B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the light emitting device 800 shown in FIG. 9B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

FIG. 10 is a schematic view showing an example of the display device using the light emitting device 100 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. An active element such as a transistor is arranged on the circuit board 1007. The battery 1008 is unnecessary if the display device 1000 is not a portable apparatus. Even when the display device 1000 is a portable apparatus, the battery 1008 need not be provided at this position. The light emitting device 100 can be applied to the display panel 1005. The pixels 106 arranged in the light emitting device 100 functioning as the display panel 1005 are connected to the control circuit including the active element such as a transistor arranged on the circuit board 1007 and operate.

The display device 1000 shown in FIG. 10 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

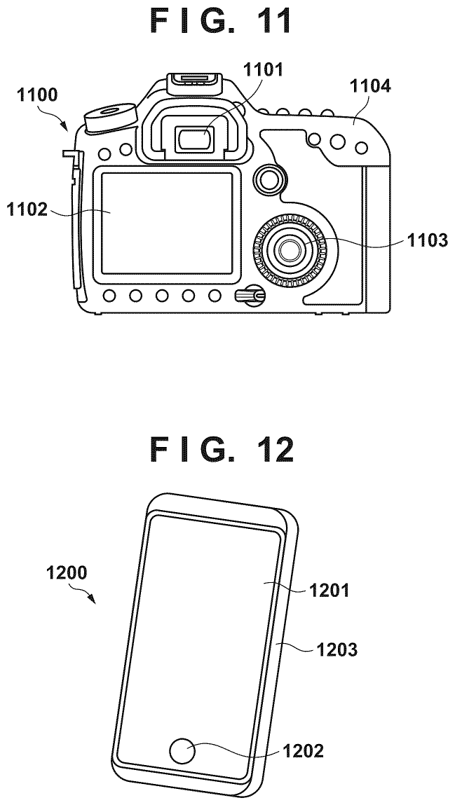

FIG. 11 is a schematic view showing an example of the photoelectric conversion device using the light emitting device 100 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 100 according to this embodiment can be applied to the viewfinder 1101 or the rear display 1102 as a display unit. In this case, the light emitting device 100 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, it is better to display the information as soon as possible. Therefore, the light emitting device 100 in which the pixel 106 including the light emitting element 105 using the organic light emitting material such as an organic EL element is arranged may be used for the viewfinder 1101 or the rear display 1102. This is so because the organic light emitting material has a high response speed. The light emitting device 100 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 100 may be applied to a display unit of an electronic apparatus. At this time, the display unit can have both a display function and an operation function. Examples of the portable terminal are a portable phone such as a smartphone, a tablet, and a head mounted display.

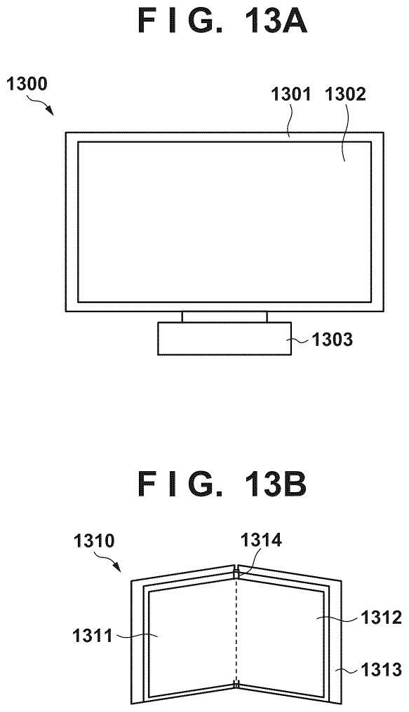

FIG. 12 is a schematic view showing an example of an electronic apparatus using the light emitting device 100 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 100 according to this embodiment can be applied to the display unit 1201.

FIGS. 13A and 13B are schematic views showing examples of the display device using the light emitting device 100 according to this embodiment. FIG. 13A shows a display device such as a television monitor or a PC monitor. A display device 1300 includes a frame 1301 and a display unit 1302. The light emitting device 100 according to this embodiment can be applied to the display unit 1302. The display device 1300 can include a base 1303 that supports the frame 1301 and the display unit 1302. The base 1303 is not limited to the form shown in FIG. 13A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 13B is a schematic view showing another example of the display device using the light emitting device 100 according to this embodiment. A display device 1310 shown in FIG. 13B can be folded, and is a so-called foldable display device. The display device 1310 includes a first display unit 1311, a second display unit 1312, a housing 1313, and a bending point 1314. The light emitting device 100 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

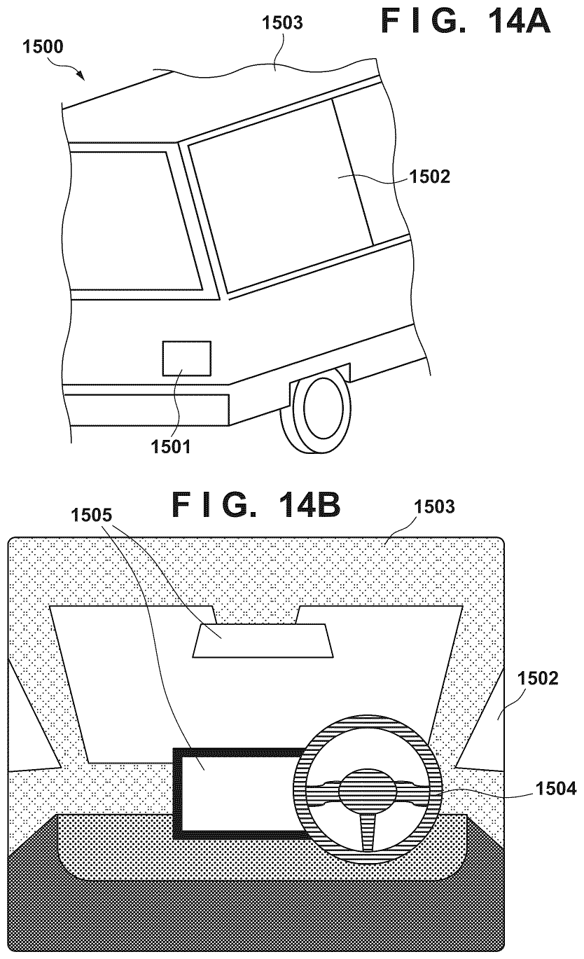

FIG. 14A is a schematic view of an automobile having a taillight as an example of a vehicle lighting appliance using the light emitting device 100 according to this embodiment. An automobile 1500 has a taillight 1501, and can have a form in which the taillight 1501 is turned on when performing a braking operation or the like. The light emitting device 100 according to this embodiment can be used as a headlight serving as a vehicle lighting appliance.

The light emitting device 100 according to this embodiment can be applied to the taillight 1501. The taillight 1501 can include a protection member for protecting the light emitting device 100 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 100 according to this embodiment may be used. In this case, the constituent materials of the electrodes and the like of the light emitting device 100 are formed by transparent members.

As shown in FIG. 14B, the automobile 1500 can include a steering wheel 1504 that controls the moving direction of the moving body (automobile), and a display unit 1505 that is mounted on the vehicle body 1503 and displays a map, the position of the moving body, a turning direction, the visual field on the rear side of the moving body, and the like. The light emitting device 100 according to this embodiment can be applied to the display unit 1505.

The automobile 1500 is an example of the moving body, and the moving body according to this embodiment includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, an aircraft propeller or fan, or the like. More specifically, the moving body may be a bicycle, an automobile, a train, a ship, an aircraft, a drone, or the like. The moving body may include a main body and a lighting appliance provided in the main body. The lighting appliance may be used to make a notification of the current position of the main body. The lighting appliance may include the light emitting device 100 according to this embodiment. The moving body may include a display unit mounted on the main body. The display unit may include the light emitting device 100 according to this embodiment.

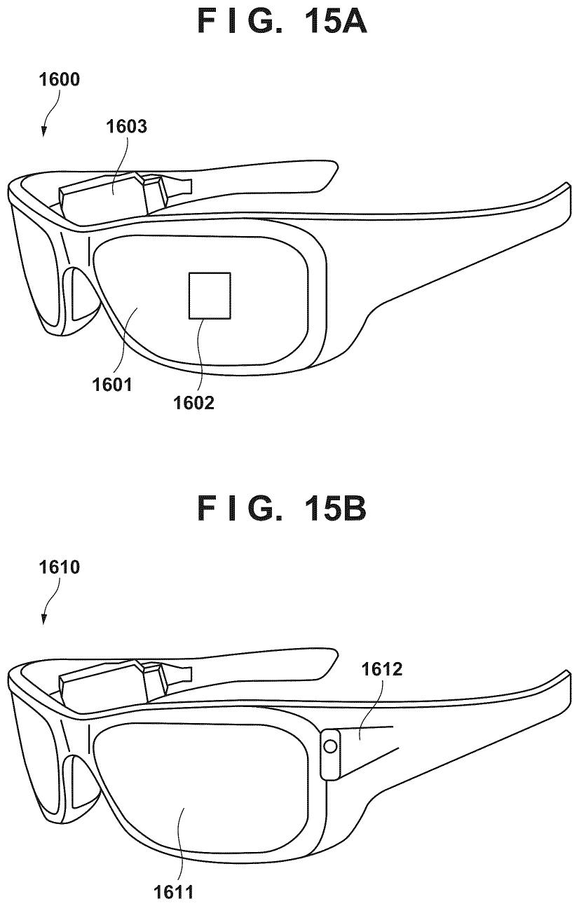

Further application examples of the light emitting device 100 according to this embodiment will be described with reference to FIGS. 15A and 15B. The light emitting device 100 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 15A. An image capturing device 1602 such as a CMOS sensor or an SPAD is provided on the surface side of a lens 1601 of the glasses 1600. In addition, the light emitting device 100 according to this embodiment is provided on the back surface side of the lens 1601.

The glasses 1600 further include a control device 1603. The control device 1603 functions as a power supply that supplies electric power to the image capturing device 1602 and the light emitting device 100 according to each embodiment. In addition, the control device 1603 controls the operations of the image capturing device 1602 and the light emitting device 100. An optical system configured to condense light to the image capturing device 1602 is formed on the lens 1601.

Glasses 1610 (smartglasses) according to one application example will be described with reference to FIG. 15B. The glasses 1610 include a control device 1612, and an image capturing device corresponding to the image capturing device 1602 and the light emitting device 100 are mounted on the control device 1612. The image capturing device in the control device 1612 and an optical system configured to project light emitted from the light emitting device 100 are formed in a lens 1611, and an image is projected to the lens 1611. The control device 1612 functions as a power supply that supplies electric power to the image capturing device and the light emitting device 100, and controls the operations of the image capturing device and the light emitting device 100. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 according to this embodiment of the present disclosure can include an image capturing device including a light receiving element, and control a displayed image based on the line-of-sight information of the user from the image capturing device.

More specifically, the light emitting device 100 decides a first visual field region at which the user is gazing and a second visual field region other than the first visual field region based on the line-of-sight information. The first visual field region and the second visual field region may be decided by the control device of the light emitting device 100, or those decided by an external control device may be received. In the display region of the light emitting device 100, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 100, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 100, the image capturing device, or an external device. If the external device holds the AI program, it is transmitted to the light emitting device 100 via communication.

When performing display control based on line-of-sight detection, smartglasses further including an image capturing device configured to capture the outside can be applied. The smartglasses can display captured outside information in real time.

According to the present disclosure, it is possible to provide a technique advantageous in suppressing reduction of a color gamut.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-167824, filed Sep. 26, 2024, which is hereby incorporated by reference herein in its entirety.

What is claimed is:

1. A light emitting device comprising:
a display region where a plurality of pixels are arranged on a main surface of a substrate,
wherein each pixel includes a light emitting region arranged on the substrate, a microlens arranged on the light emitting region, and a light shielding layer that includes an opening portion at a position overlapping a vertex of the microlens in an orthogonal projection to the main surface and covers a part of the microlens,
the plurality of pixels include a first pixel, and
in the first pixel, in the orthogonal projection to the main surface, the vertex of the microlens and a geometric centroid of the light emitting region are arranged at different positions and a distance between a geometric centroid of the opening portion and the geometric centroid of the light emitting region is shorter than a distance between the vertex of the microlens and the geometric centroid of the light emitting region.

2. The device according to claim 1, wherein in the orthogonal projection to the main surface, the geometric centroid of the light emitting region of the first pixel is arranged between a center of the display region and the vertex of the microlens of the first pixel.

3. The device according to claim 1, wherein in the first pixel, in the orthogonal projection to the main surface, the geometric centroid of the opening portion is arranged between the vertex of the microlens and the geometric centroid of the light emitting region.

4. The device according to claim 1, wherein in the orthogonal projection to the main surface, the vertex of the microlens of the first pixel, the geometric centroid of the opening portion, and the geometric centroid of the light emitting region are arranged on a virtual straight line.

5. The device according to claim 1, wherein in the orthogonal projection to the main surface, the geometric centroid of the light emitting region in each pixel is arranged at a position overlapping the microlens of each pixel.

6. The device according to claim 1, wherein in the orthogonal projection to the main surface, the distance between the vertex of the microlens and the geometric centroid of the opening portion in the first pixel is shorter than the distance between the geometric centroid of the opening portion and the geometric centroid of the light emitting region in the first pixel.

7. The device according to claim 1, wherein
the plurality of pixels include a second pixel,
the second pixel is arranged between the first pixel and a center of the display region, and in the orthogonal projection to the main surface, the vertex of the microlens and the geometric centroid of the light emitting region are arranged at different positions and the distance between the geometric centroid of the opening portion and the geometric centroid of the light emitting region is shorter than the distance between the vertex of the microlens and the geometric centroid of the light emitting region, and
in the orthogonal projection to the main surface, the distance between the vertex of the microlens and the geometric centroid of the light emitting region in the first pixel is longer than the distance between the vertex of the microlens and the geometric centroid of the light emitting region in the second pixel.

8. The device according to claim 7, wherein in the orthogonal projection to the main surface, the distance between the vertex of the microlens and the geometric centroid of the opening portion in the first pixel is longer than the distance between the vertex of the microlens and the geometric centroid of the opening portion in the second pixel.

9. The device according to claim 7, wherein a shortest distance between the microlens and an outer edge of the opening portion in the first pixel is shorter than a shortest distance between the microlens and an outer edge of the opening portion in the second pixel.

10. The device according to claim 1, wherein in the orthogonal projection to the main surface, the distance between the vertex of the microlens and the geometric centroid of the light emitting region in each of the plurality of pixels becomes longer continuously or stepwise as a distance from a center of the display region is longer.

11. The device according to claim 1, wherein in the orthogonal projection to the main surface, the distance between the vertex of the microlens and the geometric centroid of the opening portion in each of the plurality of pixels becomes longer continuously or stepwise as a distance from a center of the display region is longer.

12. The device according to claim 1, wherein in a pixel arranged at a center of the display region among the plurality of pixels, in the orthogonal projection to the main surface, the vertex of the microlens, the geometric centroid of the opening portion, and the geometric centroid of the light emitting region are arranged at positions overlapping each other.

13. The device according to claim 1, wherein
each pixel further includes a reflective layer arranged between the light emitting region and the substrate, and an optical adjustment layer arranged between the light emitting region and the reflective layer, and
the plurality of pixels include a third pixel that is different from the first pixel in terms of a thickness of the optical adjustment layer.

14. The device according to claim 13, wherein
each pixel further includes a color filter arranged between the microlens and the light emitting region, and
the color filter arranged in the first pixel and the color filter arranged in the third pixel transmit light beams of different wavelengths.

15. The device according to claim 1, wherein each pixel further includes a color filter arranged between the microlens and the light emitting region.

16. The device according to claim 1, wherein in the orthogonal projection to the main surface, the light shielding layer is arranged to further cover a space between the microlenses of the plurality of pixels.

17. The device according to claim 1, wherein the light shielding layer contains a resin containing a black pigment.

18. A display device comprising:
the light emitting device according to claim 1; and
a control circuit connected to the light emitting device.

19. A photoelectric conversion device comprising:
an optical unit including a plurality of lenses;
an image sensor configured to receive light having passed through the optical unit; and
a display configured to display an image,
wherein the display includes the light emitting device according to claim 1.

20. An electronic apparatus comprising:
a housing provided with a display; and
a communication unit provided in the housing and configured to perform external communication,
wherein the display includes the light emitting device according to claim 1.

21. A moving body comprising:
a main body; and
a lighting appliance provided in the main body,
wherein the lighting appliance includes the light emitting device according to claim 1.

22. A wearable device comprising a display device configured to display an image,
wherein the display device includes the light emitting device according to claim 1.
